(19) United States
(12) Patent Application Publication
(10) Pub. No.: US 2025/0267870 A1
(43) Pub. Date: Aug. 21, 2025

(54) NON-VOLATILE MEMORY DEVICE AND ELECTRONIC SYSTEM INCLUDING THE SAME

(71) Applicant: SAMSUNG ELECTRONICS CO., LTD., Suwon-si (KR)

(72) Inventors: Kohji KANAMORI, Suwon-si (KR); Seogoo KANG, Suwon-si (KR); Sanghun CHUN, Suwon-si (KR); Jeehoon HAN, Suwon-si (KR)

(73) Assignee: SAMSUNG ELECTRONICS CO., LTD., Suwon-si (KR)

(21) Appl. No.: 18/950,480

(22) Filed: Nov. 18, 2024

(30) Foreign Application Priority Data
Feb. 20, 2024 (KR) 10-2024-0024460

(51) Int. Cl. H10B 43/35; H10B 41/10; H10B 41/20; H10B 41/35; H10B 41/41; H10B 43/10; H10B 43/20; H10B 43/40

(52) U.S. Cl. CPC H10B 43/35; H10B 41/10; H10B 41/20; H10B 41/35; H10B 41/41; H10B 43/10; H10B 43/20; H10B 43/40

(57) ABSTRACT

A non-volatile memory device includes a plurality of gate lines, a cut structure at least partially penetrating the string selection line in the vertical direction, a channel structure disposed in a channel hole that at least partially penetrates the plurality of gate lines in the vertical direction, a bit line coupled with a first end of the channel structure, and a common source line coupled with a second end of the channel structure. The plurality of gate lines includes a string selection line, a word line above the string selection line, and a dummy word line between the string selection line and the word line, the plurality of gate lines being disposed apart from each other in a vertical direction.

### CROSS-REFERENCE TO RELATED APPLICATIONS

This application claims benefit of priority under 35 U.S.C. § 119 to Korean Patent Application No. 10-2024-0024460, filed on Feb. 20, 2024, in the Korean Intellectual Property Office, the disclosure of which is incorporated by reference herein in its entirety.

### BACKGROUND

### 1. Field

The present disclosures relates generally to a non-volatile memory device and an electronic system including the non-volatile memory device, and more particularly, to a non-volatile memory device including memory strings arranged in a vertical direction and an electronic system including the non-volatile memory device.

### 2. Description of Related Art

Memory devices capable of storing relatively large amounts of data may be needed by electronic systems for data storage. A proposed approach to potentially increase data storage capacities of memory devices may include a memory device in which memory cells may be arranged in three-dimensionally (3D) arranged memory cells rather than two-dimensionally (2D) arranged memory cells. Another proposed approach may include a memory device provided by forming a portion of the memory device on a first substrate, forming the other portion of the memory device on a second substrate, and bonding the first and second substrates to each other.

### SUMMARY

One or more example embodiments of the present disclosure provide a non-volatile memory device configured to potentially improve device performance and reliability when compared to related non-volatile memory devices.

Further, one or more example embodiments of the present disclosure provide an electronic system configured to potentially improve device performance and reliability when compared to related electronic systems.

According to an aspect of the present disclosure, a non-volatile memory device includes a plurality of gate lines, a cut structure at least partially penetrating the string selection line in the vertical direction, a channel structure disposed in a channel hole that at least partially penetrates the plurality of gate lines in the vertical direction, a bit line coupled with a first end of the channel structure, and a common source line coupled with a second end of the channel structure. The plurality of gate lines includes a string selection line, a word line above the string selection line, and a dummy word line between the string selection line and the word line, the plurality of gate lines being disposed apart from each other in a vertical direction. The channel hole includes a first portion at least partially penetrating the string selection line, a second portion at least partially penetrating the word line, and a third portion disposed between the first portion and the second portion and coupled in one piece with the first portion and the second portion. The first portion is offset from the second portion in a horizontal direction crossing the vertical direction. The channel structure includes a gate insulating layer conformally disposed on an inner wall of the channel hole, and a channel layer conformally disposed on the gate insulating layer. The gate insulating layer is disposed as one body on inner walls of the first portion, the second portion, and the third portion.

According to an aspect of the present disclosure, a non-volatile memory device includes a peripheral circuit stack and a first cell array stack on the peripheral circuit stack. The peripheral circuit stack includes a peripheral circuit board and a peripheral circuit on the peripheral circuit board. The first cell array stack includes a plurality of first gate lines, a first cut structure at least partially penetrating the first string selection line in the vertical direction, a first channel structure including a first channel layer disposed in a first channel hole that at least partially penetrates the plurality of first gate lines in the vertical direction, a first bit line coupled with the first channel layer through a first bit line pad at a first end of the first channel structure, and a first common source line coupled with the first channel layer at a second end of the first channel structure. The plurality of first gate lines includes a first string selection line, a first word line above the first string selection line, and a first dummy word line between the first string selection line and the first word line, the plurality of first gate lines being disposed apart from each other in a vertical direction. The first channel hole includes a first portion at least partially penetrating the first string selection line and a second portion at least partially penetrating the first word line. A first width in a horizontal direction of a first region of the first portion gradually increases in a first direction from the first bit line toward the first common source line, the horizontal direction crossing the vertical direction. A second width in the horizontal direction of a second region of the second portion gradually increases in a second direction away from the first portion. The first portion is offset from the second portion in the horizontal direction.

According to an aspect of the present disclosure, an electronic system includes a main board, a non-volatile memory device on the main board, and a controller on the main board and electrically coupled with the non-volatile memory device. The non-volatile memory device includes a peripheral circuit stack and a cell array stack on the peripheral circuit stack. The peripheral circuit stack includes a peripheral circuit board and a peripheral circuit on the peripheral circuit board. The cell array stack includes a plurality of gate lines, a cut structure at least partially penetrating the string selection line in the vertical direction, a channel structure including a channel layer disposed in a channel hole that at least partially penetrates the plurality of gate lines in the vertical direction, a bit line coupled with the channel layer through a bit line pad at an end of the channel structure, and a common source line coupled with the channel layer at another end of the channel structure. The plurality of gate lines includes a string selection line, a word line above the string selection line, and a dummy word line between the string selection line and the word line. The plurality of gate lines being disposed apart from each other in a vertical direction. The channel hole includes a first portion at least partially penetrating the string selection line, a second portion at least partially penetrating the word line, and a third portion disposed between the first portion and the second portion and coupled in one piece with the first portion and the second portion. A first width in a horizontal direction of a first region of the first portion gradually increases in a first direction from the bit line toward the common source line, the horizontal direction crossing the vertical direction. A second width in the horizontal direction of a second region of the second portion gradually increases in a second direction away from the first portion. At a first boundary between the first portion and the third portion, a first horizontal width of the first portion is less than a third horizontal width of the third portion. At a second boundary between the second portion and the third portion, a second horizontal width of the second portion is less than the third horizontal width of the third portion. A first center of the first portion is offset in the horizontal direction from a center of the second portion. The channel structure further includes a gate insulating layer conformally disposed on an inner wall of the channel hole. The gate insulating layer is disposed as one body on inner walls of the first portion, the second portion, and the third portion.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram illustrating a non-volatile memory device, according to embodiments;

FIG. 2 is a circuit diagram illustrating a memory block of a non-volatile memory device, according to embodiments;

FIG. 3 is a perspective diagram illustrating a configuration of a non-volatile memory device, according to embodiments;

FIG. 4 is a plan layout illustrating some elements of a non-volatile memory device, according to embodiments;

FIG. 5 is a cross-sectional diagram taken along line A-A in FIG. 4, according to embodiments;

FIG. 6 is an enlarged cross-sectional diagram illustrating a region EX1 of FIG. 5, according to embodiments;

FIG. 7 is an enlarged cross-sectional diagram illustrating a region EX2 of FIG. 6, according to embodiments;

FIG. 8 is an enlarged cross-sectional diagram illustrating a non-volatile memory device, according to embodiments;

FIG. 9 is an enlarged cross-sectional diagram illustrating a non-volatile memory device, according to embodiments;

FIGS. 10 and 11 are cross-sectional diagrams illustrating non-volatile memory devices, according to embodiments;

FIGS. 12 to 26 are cross-sectional diagrams illustrating a method of manufacturing a non-volatile memory device, according to embodiments;

FIG. 27 is a diagram schematically illustrating a data storage system including a non-volatile memory device, according to embodiments;

FIG. 28 is a perspective diagram schematically illustrating a data storage system including a non-volatile memory device, according to embodiments; and

FIG. 29 is a cross-sectional diagram schematically illustrating a semiconductor package, according to embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” “third” to be used to describe relative positions of elements. The terms “first,” “second,” “third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “AlGaAs”, “AlO”, “BN”, “GaAs”, “HfO”, “InGaAs”, “SiBN”, “SiCN”, “SiGe”, “SiN”, “SiO”, “SiOCN”, “SiON”, “TaO”, “ZrO”, and the like may refer to a material made of elements included in each of the terms and is not a chemical formula representing a stoichiometric relationship.

Hereinafter, various embodiments of the present disclosure are described with reference to the accompanying drawings.

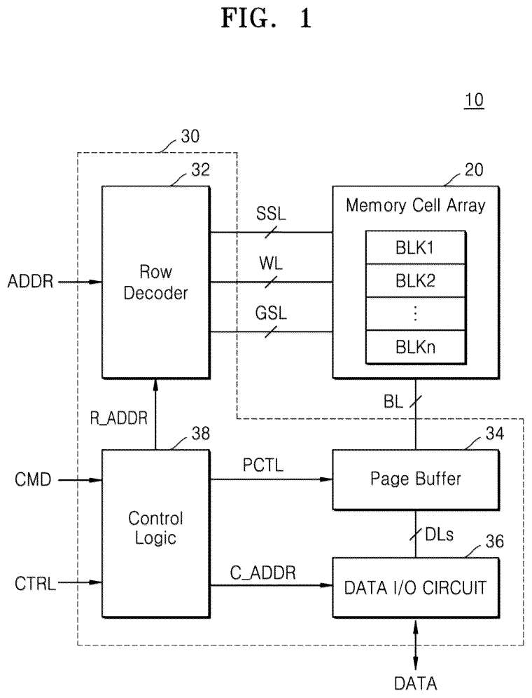

FIG. 1 is a block diagram illustrating a non-volatile memory device 10, according to embodiments.

Referring to FIG. 1, the non-volatile memory device 10 may include a memory cell array 20 and a peripheral circuit 30. The memory cell array 20 may include a plurality of memory cell blocks (e.g., a first memory cell block BLK1, a second memory cell block BLK2, . . . , and an n-th memory cell block BLKn, where n is a positive integer greater than one (1)). Each of the plurality of memory cell blocks BLK1 to BLKn may include a plurality of memory cells. The first to n-th memory cell blocks BLK1 to BLKn may be connected to the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, and control logic 38. In an embodiment, the peripheral circuit 30 may further include an I/O interface, column logic, a voltage generator, a pre-decoder, a temperature sensor, a command decoder, an address decoder, an amplifier circuit, or the like.

The memory cell array 20 may be connected to the page buffer 34 through the bit line BL, and to the row decoder 32 through the word line WL, the string selection line SSL, and the ground selection line GSL. In the memory cell array 20, each of the memory cells included in the plurality of memory cell blocks BLK1 to BLKn may be a flash memory cell. The memory cell array 20 may include a three-dimensional (3D) memory cell array. The 3D memory cell array may include a plurality of NAND strings, and each of the NAND strings may include a plurality of memory cells connected to a plurality of word lines WL that are vertically stacked above a substrate.

The peripheral circuit 30 may receive an address ADDR, a command CMD, and a control signal CTRL from the outside of the non-volatile memory device 10, and may exchange data with a device located outside the non-volatile memory device 10.

The row decoder 32 may select at least one of the plurality of memory cell blocks BLK1 to BLKn in response to an address ADDR received from the outside of the non-volatile memory device 10 and may select a word line WL, a string selection line SSL, and a ground selection line GSL of the selected at least one memory cell block. The row decoder 32 may transmit a voltage for performing a memory operation to the word line WL of the selected at least one memory cell block.

The page buffer 34 may be connected to the memory cell array 20 through the bit line BL. During a program operation, the page buffer 34 may operate as a write driver to apply a voltage to the bit line BL according to data that is to be stored in the memory cell array 20, and/or during a read operation, the page buffer 34 may operate as a sense amplifier to detect data stored in the memory cell array 20. The page buffer 34 may operate according to a control signal PCTL provided from the control logic 38.

The data I/O circuit 36 may be connected to the page buffer 34 through data lines DLs. During a program operation, the data I/O circuit 36 may receive data from a memory controller and may provide program data to the page buffer 34 based on a column address C_ADDR received from the control logic 38. During a read operation, the data I/O circuit 36 may provide read data stored in the page buffer 34 to the memory controller based on a column address C_ADDR received from the control logic 38.

The data I/O circuit 36 may transmit an input address and/or command to the control logic 38 or the row decoder 32. Alternatively or additionally, the peripheral circuit 30 may further include an electro static discharge (ESD) circuit and a pull-up/pull-down driver.

The control logic 38 may receive a command CMD and a control signal CTRL from the memory controller. The control logic 38 may provide a row address R_ADDR to the row decoder 32 and a column address C_ADDR to the data I/O circuit 36. The control logic 38 may generate, in response to the control signal CTRL, various internal control signals that may be used inside the non-volatile memory device 10. For example, the control logic 38 may adjust the level of a voltage provided to the word line WL and the bit line BL during a memory operation such as, but not limited to, a program operation, an erase operation, or the like.

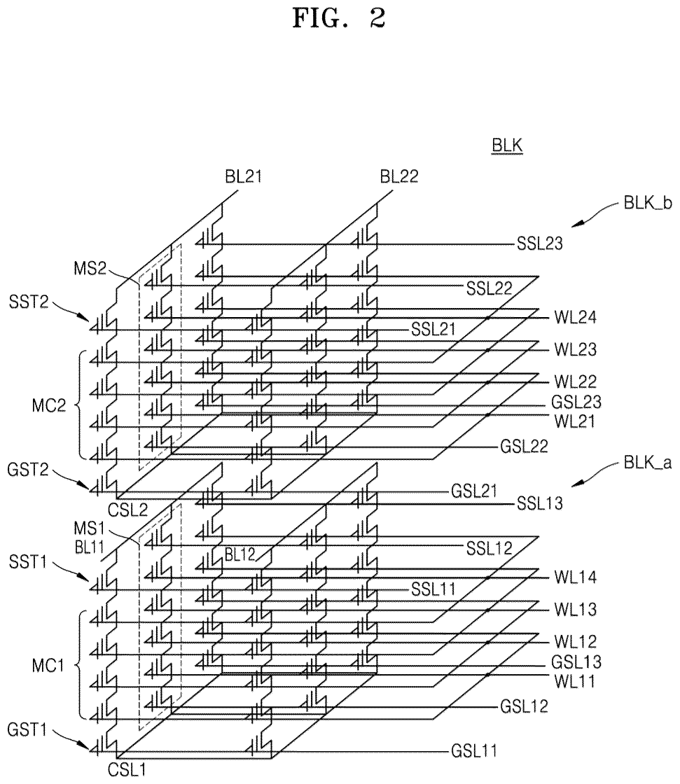

FIG. 2 is a circuit diagram illustrating a memory block BLK of a non-volatile memory device, according to embodiments.

Referring to FIG. 2, the memory block BLK may correspond to one of the plurality of memory blocks BLK1 to BLKn. The memory block BLK may include a first sub-block BLK_a and a second sub-block BLK_b that may be arranged at different vertical levels and may vertically overlap each other. The first sub-block BLK_a may include first NAND strings MS1, and the second sub-block BLK_b may include second NAND strings MS2.

Each of the first NAND strings MS1 may include a first string selection transistor SST1, a plurality of first memory cells MC1, and a first ground selection transistor GST1 that are connected in series to each other. Each of the second NAND strings MS2 may include a second string selection transistor SST2, a plurality of second memory cells MC2, and a second ground selection transistor GST2 that are connected in series to each other. The first string selection transistor SST1, the first ground selection transistor GST1, and the first memory cells MC1 included in each of the first NAND strings MS1 may form a stacked structure above a substrate in a vertical direction, and the second string selection transistor SST2, the second ground selection transistor GST2, and the second memory cells MC2 included in each of the second NAND strings MS2 may form a stacked structure stacked above the substrate in the vertical direction.

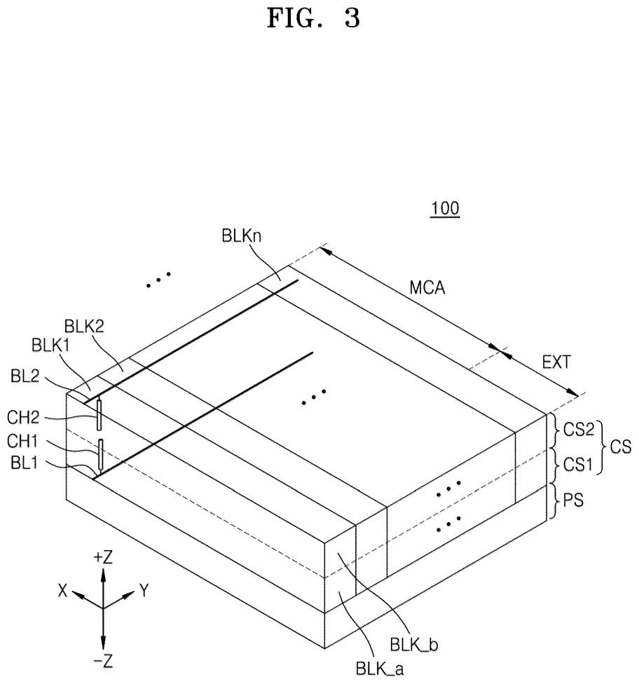

First bit lines BL1 (e.g., first bit lines BL11 and BL12) may extend above upper ends of the first NAND strings MS1 in a first direction (e.g., a Y direction in FIG. 3), and first word lines (e.g., a first word line WL11, a second word line WL12, a third word line WL13, and a fourth word line WL14) may extend in a second direction (e.g., an X direction in FIG. 3). The first NAND strings MS1 may be disposed between the first bit lines BL1 and a first common source line CSL1. The first string selection transistors SST1 may be connected to first string selection lines (e.g., a first string selection line SSL11, a second string selection line SSL12, and a third string selection line SSL13) that correspond to the first string selection transistors SST1. The first memory cells MC1 may be respectively connected to the first word lines WL11 to WL14 that correspond to the first memory cells MC1. The first ground selection transistors GST1 may be connected to first ground selection lines (e.g., a first ground selection line GSL11, a second ground selection line GSL12, and a third ground selection line GSL13) that correspond to the first ground selection transistors GST1. The first string selection transistors SST1 may be connected to bit lines that correspond to the first string selection transistors SST1, and the first ground selection transistors GST1 may be connected to the first common source line CSL1.

Second bit lines BL2 (e.g., second bit lines BL21 and BL22 may extend above upper ends of the second NAND strings MS2 in the first direction (e.g., the Y direction in FIG. 3), and second word lines (e.g., a fifth word line WL21, a sixth word line WL22, a seventh word line WL23, and an eighth word line WL24) may extend in the second direction (e.g., the X direction in FIG. 3). The second NAND strings MS2 may be disposed between the second bit lines BL2 and a second common source line CSL2. The second string selection transistor SST2 may be connected to second string selection lines (e.g., a fourth string selection line SSL21, a fifth fourth string selection line SSL22, and a fourth string selection line SSL23) that correspond to the second string selection transistors SST2. The second memory cells MC2 may be respectively connected to the second word lines WL21 to WL24 that correspond to the second memory cells MC2. The second ground selection transistors GST2 may be connected to second ground selection lines (e.g., a fourth ground selection line GSL21, a fifth ground selection line GSL22, and a sixth ground selection line GSL23) that correspond to the second ground selection transistors GST2. The second string selection transistors SST2 may be connected to bit lines that correspond to the second string selection transistors SST2, and the second ground selection transistors GST2 may be connected to the second common source line CSL2.

As used herein, the number of NAND strings, the number of word lines, the number of bit lines, the number of ground selection lines, and the number of string selection lines may vary depending on embodiments and/or design constraints.

In embodiments, the same voltage may be applied to the first word lines WL11 to WL14 and the second word lines WL21 to WL24 that correspond to the first word lines WL11 to WL14. For example, the first word line WL11 that may be a lowermost first word line and the second word line WL21 that may be a lowermost second word line may be electrically connected to a word line driving circuit (e.g., a pass transistor), and the same voltage may be applied to the lowest first word line WL11 and the lowermost second word line WL21. Similarly, the first word line WL14 that may be an uppermost word line and the second word line WL24 that may be an uppermost second word line may be electrically connected to the word line driving circuit (e.g., the pass transistor), and a similar voltage may be applied to the uppermost first word line WL14 and the uppermost second word line WL24.

In embodiments, the same voltage may be applied to the first string selection lines SSL11 to SSL13 and the second string selection lines SSL21 to SSL23 that correspond to the first selection lines SSL11 to SSL13. For example, the first string selection line SSL11 that may disposed on a left side and the second string selection line SSL21 that may be disposed on a left side may be electrically connected to a string selection line driving circuit, and the same voltage may be applied to the first string selection line SSL11 disposed on the left side and the second string selection line SSL21 disposed on the left side.

In embodiments, each of the first bit lines BL11 and BL12 may be configured such that a voltage may be applied to a corresponding first NAND string MS1 from a first page buffer circuit, and each of the second bit lines BL21 and BL22 may be configured such that a voltage may be applied to a corresponding second NAND string MS2 from a second page buffer circuit.

In embodiments, the same word line voltage may be applied to a first memory cell MC1 of a first NAND string MS1 connected to the lowermost first word line WL11 and a second memory cell MC2 of a second NAND string MS2 connected to the lowermost second word line WL21, and a bit line voltage applied to the first memory cell MC1 through the first bit line BL11 may be independent of a bit line voltage applied to the second memory cell MC2 through the second bit line BL21. Therefore, the first memory cell MC1 may be programmed independently from the second memory cell MC2.

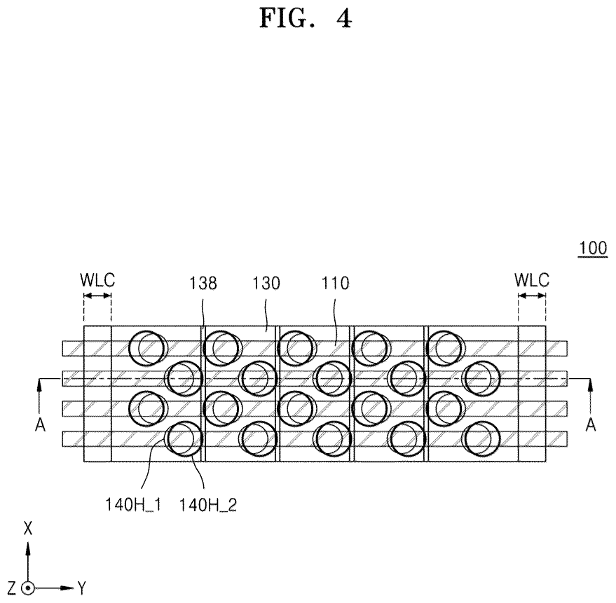

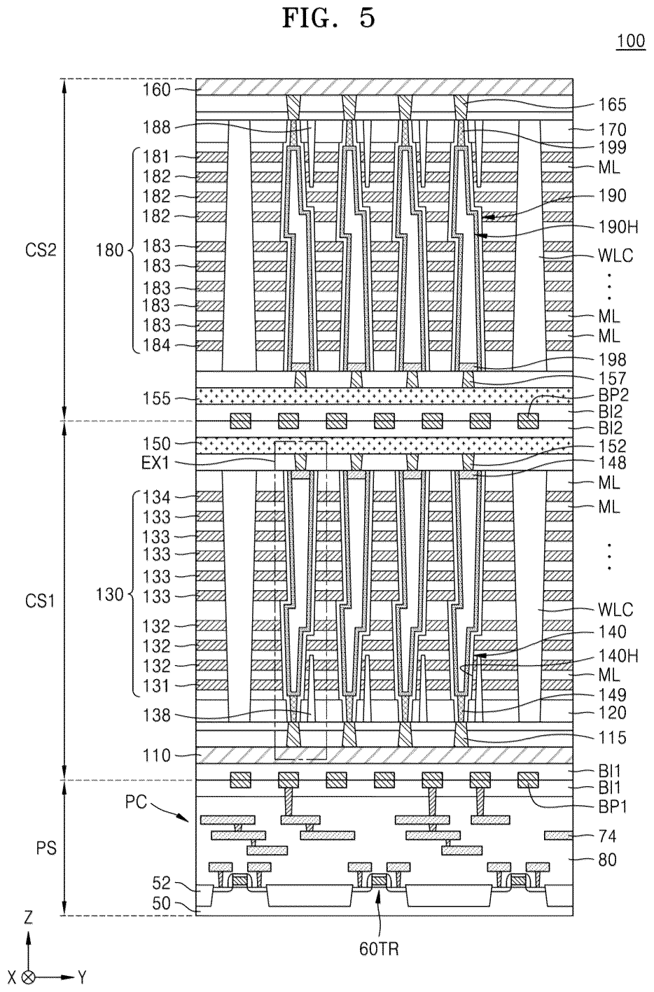

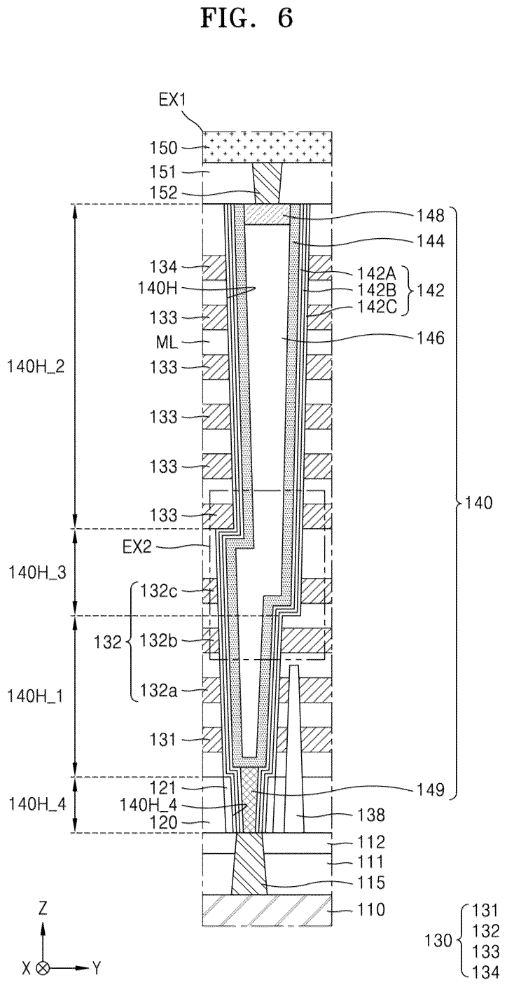

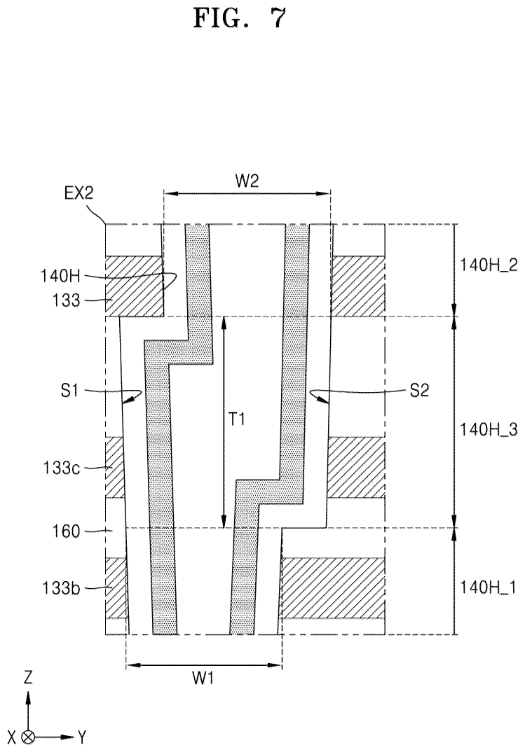

FIG. 3 is a perspective diagram illustrating a configuration of a non-volatile memory device 100, according to embodiments. FIG. 4 is a plan layout illustrating some elements of the non-volatile memory device 100, according to embodiments. FIG. 5 is a cross-sectional diagram taken along line A-A of FIG. 4, according to embodiments. FIG. 6 is an enlarged cross-sectional diagram illustrating a region EX1 of FIG. 5, according to embodiments. FIG. 7 is an enlarged cross-sectional diagram illustrating a region EX2 of FIG. 6, according to embodiments.

Referring to FIGS. 3 to 7, the non-volatile memory device 100 may include a cell array stack CS and a peripheral circuit stack PS that may overlap each other in a vertical direction (Z direction). The cell array stack CS may include the memory cell array 20 described with reference to FIG. 1, and the peripheral circuit stack PS may include the peripheral circuit 30 described with reference to FIG. 1.

The cell array stack CS may include a plurality of memory cell blocks BLK1 to BLKn. Each of the memory cell blocks BLK1 to BLKn may include memory cells that are three-dimensionally (3D) arranged. Each of the memory cell blocks BLK1 to BLKn may include a first sub-block BLK_b and a second sub-block BLK_b that may overlap each other above the peripheral circuit stack PS in the vertical direction (Z direction). The first sub-block BLK_a may include a first channel structure CH1 and a first bit line BL1 connected to the first channel structure CH1, and the second sub-block BLK_b may include a second channel structure CH2 overlapping the first channel structure CH1 and a second bit line BL2 connected to the second channel structure CH2.

In embodiments, the cell array stack CS may include a first cell array stack CS1 and a second cell array stack CS2 that may overlap each other above the peripheral circuit stack PS. The first sub-block BLK_a may be disposed in the first cell array stack CS1, and the second sub-block BLK_b may be disposed in the second cell array stack CS2.

FIG. 3 illustrates an example configuration in which the first cell array stack CS1 is disposed directly above the peripheral circuit stack PS such that the first bit line BL1 included in the first cell array stack CS1 may be closer to the peripheral circuit stack PS than the first channel structure CH1 is to the peripheral circuit stack PS, and the second cell array stack CS2 is disposed on the first cell array stack CS1 such that the second channel structure CH2 may be closer to the first cell array stack CS1 than the second bit line BL2 included in the second cell array stack CS2 is to the first cell array stack CS1. As used herein, for ease of description, a direction toward the peripheral circuit stack PS may be referred to as a −Z direction, and a direction toward the second cell array stack CS2 may be referred to as a Z direction. However, the present disclosure is not limited in this regard, and the direction toward the second cell array stack CS2 may be referred to as a −Z direction, for example.

Referring to FIG. 5, the peripheral circuit stack PS may include a peripheral circuit board 50 and a peripheral circuit PC disposed on the peripheral circuit board 50. Active regions may be defined on an active surface of the peripheral circuit board 50 by an isolation layer 52, and a plurality of peripheral circuit transistors 60TR may be formed on the active regions of the peripheral circuit board 50. The peripheral circuit PC may include peripheral circuit wiring structures 74 above the active regions of the peripheral circuit board 50 and an interlayer insulating layer 80 covering the peripheral circuit wiring structures 74. In addition, at least portions of the peripheral circuit wiring structures 74 may be connected to first bonding pads BP1 arranged at an interface between the peripheral circuit stack PS and the first cell array stack CS1.

The first cell array stack CS1 may be disposed on the peripheral circuit stack PS. In embodiments, a first bonding layer BI1 may be disposed at a boundary between the peripheral circuit stack PS and the first cell array stack CS1. The first bonding layer BI1 may be formed as a stacked structure of a plurality of insulating layers and may include, for example, at least one of silicon oxide (SiO), silicon nitride (SiN), silicon oxynitride (SiON), silicon carbon nitride (SiCN), or the like.

In embodiments, the first bonding pads BP1 may be arranged at the boundary between the peripheral circuit stack PS and the first cell array stack CS1. The first bonding pads BP1 may be surrounded by the first bonding layer BI1. The first bonding pads BP1 may include upper pad portions in the first cell array stack CS1 and lower pad portions in the peripheral circuit stack PS, and the upper pad portions and the lower pad portions may vertically overlap each other and may adhere to each other. For example, interfaces between the upper pad portions and the lower pad portions (e.g., bonding interfaces) may correspond to the interface between the peripheral circuit stack PS and the first cell array stack CS1. The first bonding pads BP1 may include, but not be limited to, copper (Cu). For example, the peripheral circuit stack PS and the first cell array stack CS1 may be stacked by a metal-oxide hybrid bonding method.

In some embodiments, however, the first cell array stack CS1 may be sequentially formed on the peripheral circuit stack PS by a direct stack method, and in such an embodiment, the first bonding pads BP1 may be omitted.

The first cell array stack CS1 may include a first bit line 110, a plurality of first gate lines 130, first channel structures 140, and a first common source line 150.

The first gate lines 130 may be apart from the first bit line 110 in the vertical direction (Z direction). For example, the first gate lines 130 and a plurality of mold insulating layers ML may be alternately arranged above the first bit line 110.

In embodiments, a lowest first gate line 130 among the first gate lines 130 (or a first gate line 130 disposed closest to the first bit line 110) may be a first string selection line 131. An uppermost first gate line 130 among the first gate lines 130 (or a first gate line 130 disposed farthest from the first bit line 110) may be a first ground selection line 134. Among the first gate lines 130, one or more first gate lines 130 disposed close to the first string selection line 131 may be first dummy word lines 132. Among the first gate lines 130, a remainder of the first gate lines 130, that is, first gate lines 130 disposed between the one or more first dummy word lines 132 and the first ground selection line 134, may be first word lines 133. The one or more first dummy word lines 132 may be disposed between the first string selection line 131 and the first word lines 133 to prevent the first string selection line 131 and the first word lines 133 from disturbing each other as being electrically coupled to each other. Unlike the first word lines 133, the one or more first dummy word lines 132 may not be involved in the role of memory cells.

In embodiments, the first string selection line 131 may correspond to the first string selection lines SSL11 to SSL13 described with reference to FIG. 2. The first word lines 133 may correspond to the first word lines WL11 to WL14 described with reference to FIG. 2. The first ground selection line 134 may correspond to the first ground selection lines GSL1 to GSL13 described with reference to FIG. 2.

The first channel structures 140 may be disposed in first channel holes 140H extending through the first gate lines 130 in the vertical direction (Z direction). The first channel structures 140 may be arranged apart from each other at predetermined intervals in a first horizontal direction (X direction), a second horizontal direction (Y direction), and a third horizontal direction (e.g., a diagonal direction). The first channel structures 140 may be arranged in a zigzag shape or a staggered shape.

The first bit line 110, the first gate lines 130, the first channel structures 140, and the first common source line 150 are further described with reference to FIG. 6.

Referring to FIG. 6, the first gate lines 130 and the mold insulating layers ML may be alternately arranged in the vertical direction (Z direction). The first channel holes 140H may penetrate the first gate lines 130 in the vertical direction (Z direction).

In embodiments, each of the first channel hole 140H may include a first portion 140H_1 that may penetrate the first string selection line 131 and may extend in the vertical direction (Z direction). The first portion 140H_1 may have a horizontal width continuously varying in the vertical direction (Z direction). For example, the horizontal width of the first portion 140H_1 may gradually increase from the first bit line 110 toward the first common source line 150. As another example, the horizontal width of the first portion 140H_1 may have a region that gradually increases in a direction from the first bit line 110 toward the first common source line 150.

The first portion 140H_1 of the first channel hole 140H may penetrate the first string selection line 131 and some of the one or more first dummy word lines 132. In embodiments, the first portion 140H_1 may penetrate some of the one or more first dummy word lines 132 that may be disposed close (e.g., relatively near) to the first string selection line 131. For example, the first portion 140H_1 may penetrate first dummy word lines 132a and 132b that may be disposed close to the first string selection line 131 among one or more first dummy word lines 132a, 132b, and 132c. For example, the first portion 140H_1 may overlap, in the second horizontal direction (Y direction), the first dummy word lines 132a and 132b that may be disposed close to the first string selection line 131 among the one or more first dummy word lines 132a, 132b, and 132c.

For example, the first portion 140H_1 may not penetrate the first dummy word line 132c that is closest to the first word lines 133 among the one or more first dummy word lines 132a, 132b, and 132c. As another example, the first portion 140H_1 may not overlap, in the second horizontal direction (Y direction), the first dummy word line 132c that is closest to the first word lines 133 among the one or more first dummy word lines 132a, 132b, and 132c.

For example, the first portion 140H_1 may not penetrate the first word lines 133. As another example, the first portion 140H_1 may not overlap the first word lines 133 in the second horizontal direction (Y direction).

In embodiments, the first channel hole 140H may include a second portion 140H_2 that may penetrate the first word lines 133 and may extend in the vertical direction (Z direction). The second portion 140H_2 may have a horizontal width continuously varying in the vertical direction (Z direction). For example, the horizontal width of the second portion 140H_2 may gradually increase in a direction away from the first portion 140H_1. As another example, the horizontal width of the second portion 140H_2 may have a region that gradually increases in a direction away from the first portion 140H_1. The second portion 140H_2 may further penetrate the first ground selection line 134.

For example, the second portion 140H_2 may not penetrate the one or more first dummy word lines 132a, 132b, and 132c. As another example, the second portion 140H_2 may not penetrate at least some of the one or more first dummy word lines 132a, 132b, and 132c. As another example, the second portion 140H_2 may not overlap at least some of the one or more first dummy word lines 132a, 132b, and 132c in the second horizontal direction (Y direction).

In embodiments, the centers of the first and second portions 140H_1 and 140H_2 of the first channel hole 140H may be offset from each other. For example, the centers of the first and second portions 140H_1 and 140H_2 of the first channel hole 140H may be offset in the second horizontal direction (Y direction).

The first channel hole 140H may further include a third portion 140H_3 between the first portion 140H_1 and the second portion 140H_2. The third portion 140H_3 may be connected in one piece to the first portion 140H_1 and the second portion 140H_2. A step may be provided between the first portion 140H_1 and the third portion 140H_3, and a step may be provided between the second portion 140H_2 and the third portion 140H_3. For example, the horizontal width of the first channel hole 140H may discontinuously vary at a boundary between the first portion 140H_1 and the third portion 140H_3 and a boundary between the second portion 140H_2 and the third portion 140H_3.

In embodiments, the horizontal width of the first portion 140H_1 may be less than the horizontal width of the third portion 140H_3 at the boundary between the first portion 140H_1 and the third portion 140H_3. In embodiments, the horizontal width of the second portion 140H_2 may be less than the horizontal width of the third portion 140H_3 at the boundary between the second portion 140H_2 and the third portion 140H_3.

The third portion 140H_3 of the first channel hole 140H may penetrate at least some of the one or more first dummy word lines 132. For example, the third portion 140H_3 of the first channel hole 140H may penetrate at least some (e.g., the first dummy word line 132c) of the one or more first dummy word lines 132. As another example, the third portion 140H_3 of the first channel hole 140H may overlap at least some (e.g., the first dummy word line 132c) of the one or more first dummy word lines 132 in the second horizontal direction (Y direction). The third portion 140H_3 of the first channel hole 140H may not overlap some of the one or more first dummy word lines 132 in the second horizontal direction (Y direction).

The third portion 140H_3 of the first channel hole 140H may include a first side wall S1 (as shown in FIG. 7) and a second side wall S2 (as shown in FIG. 7) that may be opposite to each other. The first side wall S1 of the third portion 140H_3 may extend in a vertical downward direction (−Z direction), and a portion of the first side wall S1 that extends in the vertical downward direction (−Z direction) may form a side wall of the first portion 140H_1. The second side wall S2 of the third portion 140H_3 may extend in the vertical direction (+Z direction), and a portion of the second side wall S2 that extends in the vertical direction (+Z direction) may form a side wall of the second portion 140H_2.

In embodiments, some of the one or more first dummy word lines 132 (e.g., the first dummy word line 132a) may overlap the first portion 140H_1 of the first channel hole 140H and a first cut structure 138 in the second horizontal direction (Y direction).

In embodiments, some of the one or more first dummy word lines 132 (e.g., the first dummy line 132b) may overlap the first portion 140H_1 of the first channel hole 140H in the second horizontal direction (Y direction) and may not overlap the first cut structure 138 in the second horizontal direction (Y direction).

In embodiments, a remainder of the one or more first dummy word lines 132 (e.g., the first dummy word line 132c) may overlap the third portion 140H3 of the first channel hole 140H in the second horizontal direction (Y direction) and may not overlap the first cut structure 138 in the second horizontal direction (Y direction).

The first channel hole 140H may further include a fourth portion 140H_4 between the first portion 140H_1 and the first bit line 110. An insulating liner 121 may be disposed on an outer wall of the fourth portion 140H_4. A step may be provided between the first portion 140H_1 and the fourth portion 140H_4. For example, the horizontal width of the first channel hole 140H may vary discontinuously at a boundary between the first portion 140H_1 and the fourth portion 140H_4. For example, the horizontal width of the first portion 140H_1 may be greater than the horizontal width of the fourth portion 140H_4 at the boundary between the first portion 140H_1 and the fourth portion 140H_4.

In embodiments, each of the first portion 140H_1, the second portion 140H_2, the third portion 140H_3, and the fourth portion 140H_4 may not include a step on an outer wall thereof. For example, the horizontal width of each of the first portion 140H_1, the second portion 140H_2, the third portion 140H_3, and the fourth portion 140H_4 may be constant or continuously vary in the vertical direction (Z direction).

A first channel structure 140 may be disposed in the first channel hole 140H. The first channel structure 140 may include a gate insulating layer 142, a channel layer 144, a buried insulating layer 146, a first source line pad 148, and a first bit line pad 149.

The gate insulating layer 142 may be conformally disposed on a side wall of the first channel hole 140H. For example, the gate insulating layer 142 may be conformally disposed on side walls of the first portion 140H_1, the second portion 140H_2, the third portion 140H_3, and the fourth portion 140H_4 of the first channel hole 140H. The gate insulating layer 142 may be disposed as one body on the side walls of the first portion 140H_1, the second portion 140H_2, the third portion 140H_3, and the fourth portion 140H_4 of the first channel hole 140H.

The channel layer 144 may be conformally disposed on the gate insulating layer 142. For example, the channel layer 144 may be conformally disposed on the gate insulating layer 142 in the first portion 140H_1, the second portion 140H_2, and the third portion 140H_3. The channel layer 144 may not be disposed in the fourth portion 140H_4 of the first channel hole 140H. The channel layer 144 may be disposed as one body on the side walls of the first portion 140H_1, the second portion 140H_2, and the third portion 140H_3.

The buried insulating layer 146 may be disposed on the channel layer 144 to fill the remaining space of the first channel hole 140H. The first source line pad 148 making contact with the channel layer 144 and blocking an entrance of the first channel hole 140H may be disposed on an upper side of the first channel hole 140H. In some embodiments, the buried insulating layer 146 may be omitted, and the channel layer 144 may be formed in a pillar shape to fill the remaining portion of the first channel hole 140H.

For example, as shown in FIG. 6, the gate insulating layer 142 may have a structure including a tunneling dielectric layer 142A, a charge storage layer 142B, and a blocking dielectric layer 142C that may be sequentially provided on an outer wall of the channel layer 144. The relative thicknesses of the tunneling dielectric layer 142A, the charge storage layer 142B, and the blocking dielectric layer 142C of the gate insulating layer 142 are not limited to those illustrated in FIG. 6 and may be modified in various ways.

The tunneling dielectric layer 142A may include, but not be limited to, silicon oxide (SiO), hafnium oxide (HfO), aluminum oxide (AlO), zirconium oxide (ZrO), tantalum oxide (TaO), or the like. The charge storage layer 142B may be and/or may include a region in which electrons coming from the channel layer 144 through the tunneling dielectric layer 142A may be stored, and may include, but not be limited to, silicon nitride (SiN), boron nitride (BN), silicon boron nitride (SiBN), or polysilicon doped with a dopant. The blocking dielectric layer 142C may include, but not be limited to, silicon oxide (SiO), silicon nitride (SiN), or a metal oxide that has a higher dielectric constant than silicon oxide (SiO). The metal oxide may be, but not be limited to, hafnium oxide (HfO), aluminum oxide (AlO), zirconium oxide (ZrO), tantalum oxide (TaO), or a combination thereof.

The first bit line pad 149 may be disposed in the fourth portion 140H_4 of the first channel hole 140H. The first bit line pad 149 may be surrounded by a first substrate 120 and the insulating liner 121. The first bit line pad 149 may be buried in the first substrate 120. For example, the first substrate 120 may include an oxide. As another example, the first bit line pad 149 may include polysilicon doped with an n-type dopant. As another example, the first bit line pad 149 may include n+ polysilicon having a higher dopant concentration than the channel layer 144.

The first cut structure 138 may penetrate the first string selection line 131 in the vertical direction (Z direction). The first cut structure 138 may penetrate the first string selection line 131 and some of the one or more first dummy word lines 132. In embodiments, the first cut structure 138 may penetrate some of the one or more first dummy word lines 132 that are disposed close to the first string selection line 131. For example, the first cut structure 138 may penetrate the first dummy word line 132a that is disposed close to the first string selection line 131 among the one or more first dummy word lines 132a, 132b, and 132c.

For example, the first cut structure 138 may overlap the first string selection line 131 and some of the one or more first dummy word lines 132 (e.g., the first dummy word line 132a) in the second horizontal direction (Y direction).

In embodiments, the first cut structure 138 may not overlap the first portion 140H_1 of the first channel hole 140H in the vertical direction (Z direction). The first cut structure 138 may overlap at least a portion of the second portion 140H_2 of the first channel hole 140H in the vertical direction (Z direction).

In the present disclosure, the centers of the first and second portions 140H_1 and 140H_2 of the first channel hole 140H are offset from each other in the second horizontal direction (Y direction) such that the first portion 140H_1 may not overlap the first cut structure 138 in the vertical direction (Z direction) and the second portion 140H_2 may overlap the first cut structure 138 in the vertical direction (Z direction).

For example, as the centers of each of the first and second portions 140H_1 140H_2 of the first channel hole 140H are offset from each other in the second horizontal direction (Y direction), the first cut structure 138 may be apart in the second horizontal direction (Y direction) from a portion of the first channel structure 140 provided in the first channel hole 140H.

That is, in embodiments, the centers of the first and second portions 140H_1 and 140H_2 of the first channel hole 140H of the non-volatile memory device 100 may be offset from each other, and thus, the first cut structure 138 may not interfere with the first channel structure 140. As a result, the performance and reliability of the non-volatile memory device 100 may be improved.

In embodiments, the first cut structure 138 may not overlap the first word lines 133 in the second horizontal direction (Y direction).

For example, owing to the one or more first dummy word lines 132 disposed between the first string selection line 131 and the first word lines 133, a process margin for preventing the first cut structure 138 from extending to the first word lines 133 may be secured. As another example, as the one or more first dummy word lines 132 are disposed between the first string selection line 131 and the first word lines 133, the first cut structure 138 may not overlap the first word lines 133 in the second horizontal direction (Y direction).

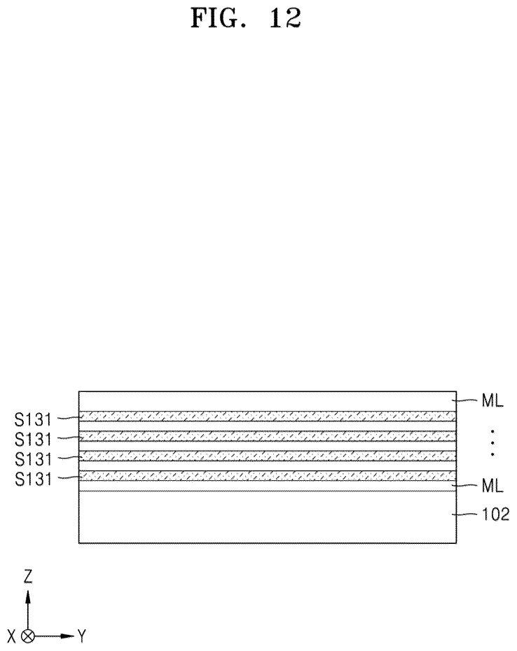

Referring to FIG. 7, the maximum horizontal width of the first portion 140H_1 of the first channel hole 140H may be less than or equal to the maximum horizontal width of the first channel hole 140H. In embodiments, the maximum horizontal width of the first portion 140H_1 of the first channel hole 140H may be the width of the first portion 140H_1 at the boundary between the first portion 140H_1 and the third portion 140H_3. For example, the maximum horizontal width of the first portion 140H_1 of the first channel hole 140H may be a first width W1. In embodiments, as described with reference to FIGS. 12 to 26, a method of manufacturing the first channel hole 140H may provide for the maximum horizontal width of the first channel hole 140H being substantially similar and/or the same as the maximum horizontal width of the second portion 140H_2.

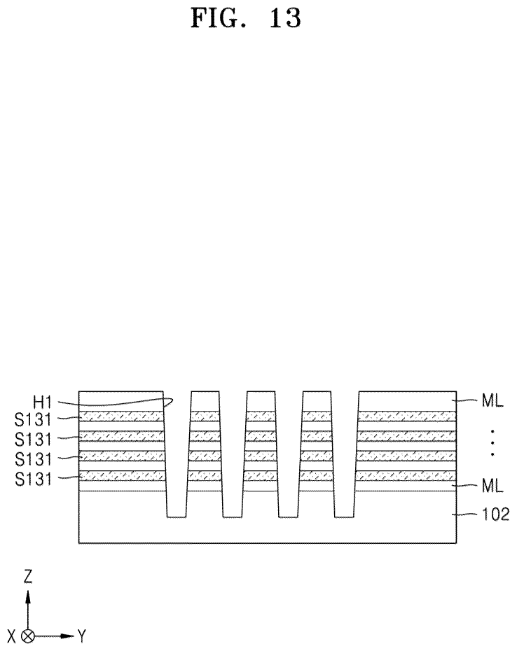

For example, as described with reference to FIGS. 13 to 16, when the first channel hole 140H is formed, a first hole H1 may be first formed, and then, a second hole H2 overlapping a portion of the first hole H1 may be formed. In such an embodiment, the first hole H1 and the second hole H2 may be formed by etching a plurality of mold insulating layers ML and sacrificial layers S131 and S132 in a vertical downward direction, and thus, the first channel hole 140H may be formed in a state in which the maximum horizontal width of the first portion 140H_1 of the first channel hole 140H is less than or equal to the maximum horizontal width of the first channel hole 140H.

Continuing to refer to FIG. 7, in the first channel hole 140H, the horizontal width of the second portion 140H_2 at the boundary between the second portion 140H_2 and the third portion 140H_3 (e.g., a second width W2) may be less than or equal to a vertical thickness T1 of the third portion 140H_3. Consequently, the gate insulating layer 142 may not block the first channel hole 140H when the gate insulating layer 142 is formed on an inner wall of the first channel hole 140H to form the first channel structure 140.

Referring to FIGS. 5 and 6, the first bit line 110 may be disposed at an end of the first channel structure 140. The first bit line 110 may be connected to the end of the first channel structure 140 through a first bit line contact 115 penetrating a first insulating layer 111 and an etch stop layer 112. For example, the first bit line 110 may be connected to the channel layer 144 of the first channel structure 140 through the first bit line contact 115 and the first bit line pad 149. As another example, the first insulating layer 111 may include, but not be limited to, an oxide, and the etch stop layer 112 may include, but not be limited to, a nitride.

The first common source line 150 may be disposed at the other end of the first channel structure 140. The first common source line 150 may be connected to the other end of the first channel structure 140 through a first source line contact 152. For example, the first common source line 150 may be connected to the channel layer 144 of the first channel structure 140 through the first source line contact 152 and the first source line pad 148. The first source line contact 152 may be surrounded by a second insulating layer 151. The second insulating layer 151 may include, but not be limited to, an oxide.

For example, the first common source line 150 may include silicon (Si), germanium (Ge), silicon germanium (SiGe), gallium arsenide (GaAs), indium gallium arsenide (InGaAs), aluminum gallium arsenide (AlGaAs), or a mixture thereof. In addition, the first common source line 150 may include a semiconductor doped with an n-type dopant. In addition, the first common source line 150 may have a crystalline structure including at least one of a single crystalline structure, an amorphous structure, a polycrystalline structure, or the like. In some examples, the first common source line 150 may include, but not be limited to, polysilicon doped with an n-type dopant.

In embodiments, the horizontal width of the end of the first channel structure 140 connected to the first bit line 110 may be less than the horizontal width of the other end of the first channel structure 140 connected to the first common source line 150. For example, in the second horizontal direction (Y direction), the end of the first channel structure 140 connected to the first bit line 110 may be less than the width of the other end of the first channel structure 140 connected to the first common source line 150.

In embodiments, the horizontal width of the first bit line pad 149 connected to the first bit line 110 may be less than the horizontal width of the first source line pad 148 connected to the first common source line 150. For example, in the second horizontal direction (Y direction), the width of the first bit line pad 149 connected to the first bit line 110 may be less than the width of the first source line pad 148 connected to the first common source line 150

A word line cut structure WLC penetrating the first gate lines 130 may be disposed on the first common source line 150. The word line cut structure WLC may include, but not be limited to, a silicon oxide (SiO) film, a silicon nitride (SiN) film, a silicon oxynitride (SiON), a silicon oxycarbonitride (SiOCN), a silicon carbon nitride (SiCN) film, or a combination thereof.

Referring again to FIG. 5, the second cell array stack CS2 may be disposed on the first cell array stack CS1. In embodiments, a second bonding layer BI2 may be disposed at a boundary between the first cell array stack CS1 and the second cell array stack CS2. The second bonding layer BI2 may be formed as a stacked structure of a plurality of insulating layers, and may include, for example, at least one of silicon oxide (SiO), silicon nitride (SiN), silicon oxynitride (SiON), silicon carbon nitride (SiCN), or the like. In embodiments, second bonding pads BP2 may be disposed at the boundary between the first cell array stack CS1 and the second cell array stack CS2. The second bonding pads BP2 may be surrounded by the second bonding layer BI2. The second bonding pads BP2 may each include an upper pad portion in the second cell array stack CS2 and a lower pad portion in the first cell array stack CS1, and the upper pad portion and the lower pad portion may vertically overlap each other and may adhere to each other. For example, an interface between the upper pad portion and the lower pad portion (e.g., a bonding interface) may be an interface between the first cell array stack CS1 and the second cell array stack CS2. The second bonding pads BP2 may include, but not be limited to, copper (Cu). For example, the first cell array stack CS1 and the second cell array stack CS2 may be stacked by a metal-oxide hybrid bonding method.

In some embodiments, the second cell array stack CS2 may be sequentially formed on the first cell array stack CS1 by a direct stack method, and in such embodiments, the second bonding pads BP2 may be omitted.

The second cell array stack CS2 may include a second bit line 160, a plurality of second gate lines 180, second channel structures 190, and a second common source line 155. The structure of the second cell array stack CS2 may be symmetrical to the structure of the first cell array stack CS1 with respect to the boundary between the first cell array stack CS1 and the second cell array stack CS2, and thus, a description of the second cell array stack CS2 may be similar to the description of the first cell array stack CS1. For example, the second bit line 160, the second gate lines 180, the second channel structures 190, and the second common source line 155 of the second cell array stack CS2 may be opposite to the first bit line 110, the first gate lines 130, the first channel structures 140, and the first common source line 150 of the first cell array stack CS1.

The second gate lines 180 may be disposed under the second bit line 160 apart from each other in the vertical direction (Z direction). For example, the second gate lines 180 and a plurality of mold insulating layers ML may be alternately disposed under the second bit line 160.

In embodiments, the second gate lines 180 may include a second string selection line 181, second dummy word lines 182, second word lines 183, and a second ground selection line 184 that may be sequentially disposed under the second bit line 160. Second cut structures 188 may penetrate the second string selection line 181.

The second channel structures 190 may be disposed in second channel holes 190H that extend through the second gate lines 180 in the vertical direction (Z direction).

The second bit line 160 may be disposed above the second channel structures 190 and may be connected to the second channel structures 190 through second bit line contacts 165. For example, the second bit line 160 may be connected to channel layers of the second channel structures 190 through second bit line pads 199 and the second bit line contacts 165. The second bit line pads 199 may be buried in a second substrate 170.

The second common source line 155 may be connected to the second channel structures 190 through second source line contacts 157. For example, the second common source line 155 may be connected to the channel layers of the second channel structures 190 through the second source line contacts 157 and second source line pads 198.

In embodiments, the second common source line 155 of the second cell array stack CS2 may be disposed between the first cell array stack CS1 and the second channel structures 190. In embodiments, the second bit line 160 of the second cell array stack CS2 may be apart from the second common source line 155 with the second channel structures 190 therebetween.

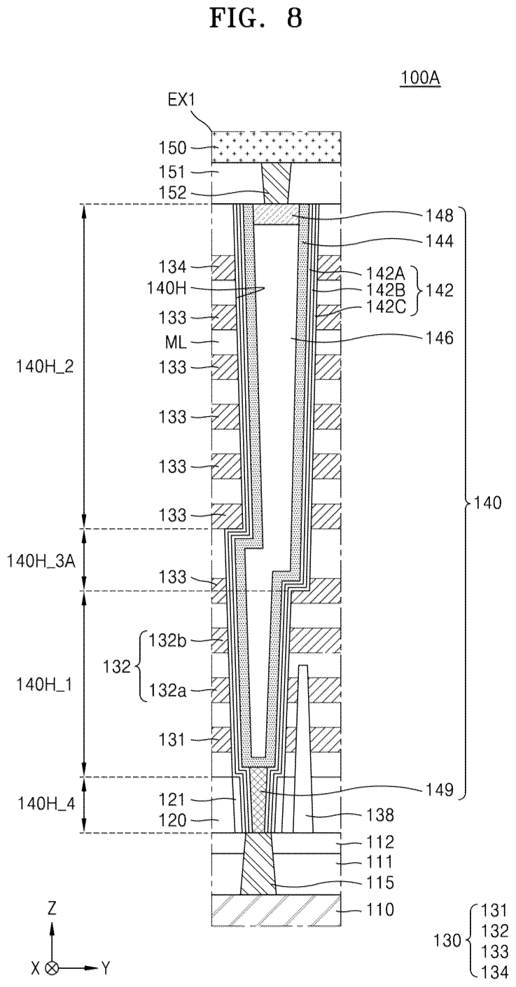

FIG. 8 is an enlarged cross-sectional diagram illustrating a non-volatile memory device 100A, according to embodiments. For example, FIG. 8 is an enlarged cross-sectional diagram illustrating a region corresponding to the region EX1 of FIG. 5. The non-volatile memory device 100A may include and/or may be similar in many respects to the non-volatile memory device 100 described above with reference to FIGS. 3 to 7, and may include additional features not mentioned above. Consequently, repeated descriptions of the non-volatile memory device 100A described above with reference to FIGS. 3 to 7 may be omitted for the sake of brevity.

Referring to FIG. 8, a plurality of first gate lines 130 may be arranged above a first bit line 110 apart from each other in a vertical direction (Z direction).

The first gate lines 130 may include a first string selection line 131, one or more first dummy word lines 132, first word lines 133, and a first ground selection line 134. A first channel structure 140 may be disposed in a first channel hole 140H that extends through the first gate lines 130 in the vertical direction (Z direction).

The first channel hole 140H may include a first portion 140H_1 that may penetrate the first string selection line 131 and may extend in the vertical direction (Z direction). The first channel hole 140H may include a second portion 140H_2 that may penetrate the first word lines 133 and may extend in the vertical direction (Z direction). The first channel hole 140H may further include a third portion 140H_3A between the first portion 140H_1 and the second portion 140H_2.

In embodiments, the third portion 140H_3A may overlap at least some of the one or more first dummy word lines 132 in a second horizontal direction (Y direction). For example, the third portion 140H_3A may overlap a first dummy word line 132b among the one or more first dummy word lines 132 in the second horizontal direction (Y direction). As another example, the third portion 140H_3A may overlap a portion of the first dummy word line 132b in the second horizontal direction (Y direction). As another example, the third portion 140H_3A may not overlap the other portion of the first dummy word line 132b in the second horizontal direction (Y direction).

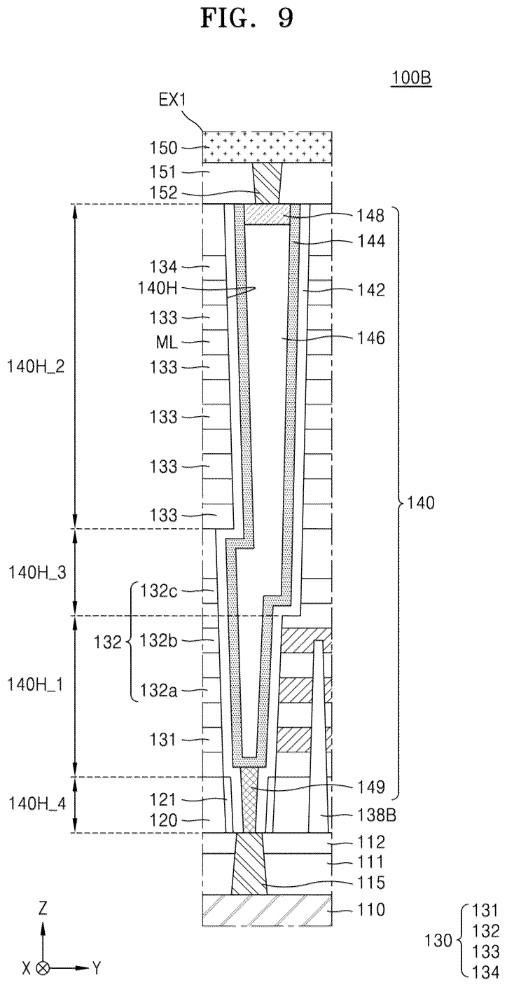

FIG. 9 is an enlarged cross-sectional diagram illustrating a non-volatile memory device 100B, according to embodiments. The non-volatile memory device 100B may include and/or may be similar in many respects to the non-volatile memory devices 100 and 100A described above with reference to FIGS. 3 to 8, and may include additional features not mentioned above. Consequently, repeated descriptions of the non-volatile memory device 100B described above with reference to FIGS. 3 to 8 may be omitted for the sake of brevity

Referring to FIG. 9, the centers of a first portion 140H_1 and a second portion 140H_2 of a first channel hole 140H of the non-volatile memory device 100B may overlap each other in a second horizontal direction (Y direction), and a first cut structure 138B may not overlap the first portion 140H_1 and the second portion 140H_2 of the first channel hole 140H in a vertical direction (Z direction).

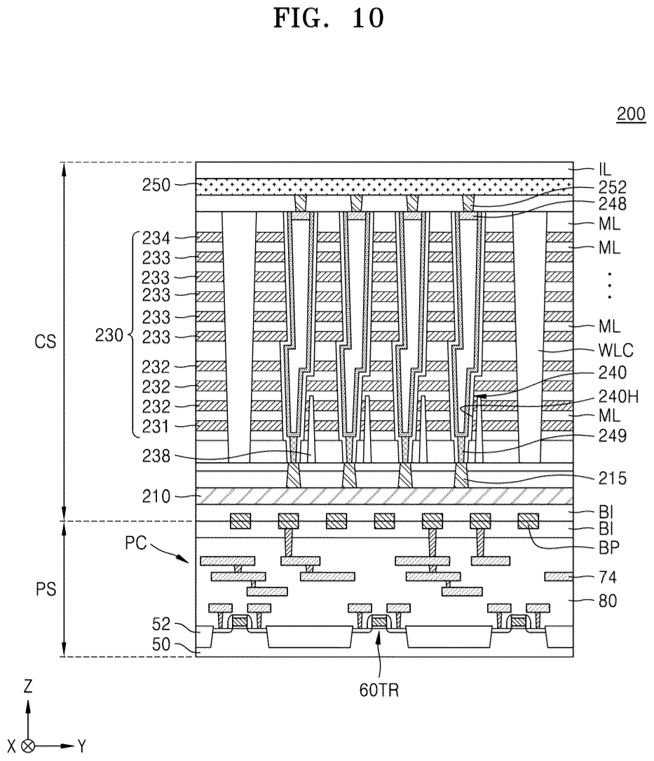

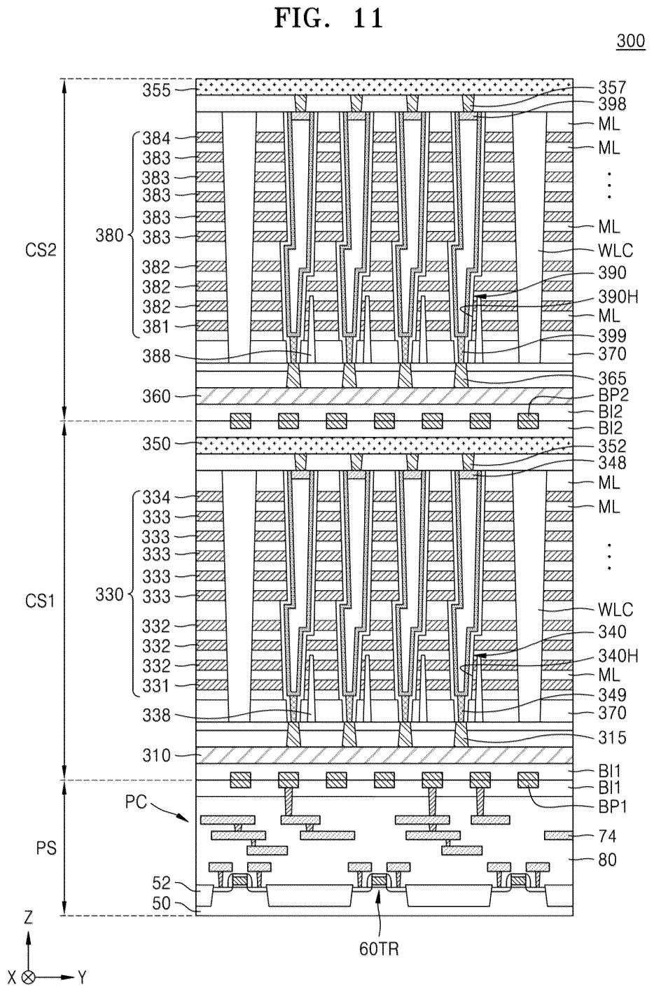

FIGS. 10 and 11 are cross-sectional diagrams illustrating non-volatile memory devices 200 and 300, according to embodiments.

Referring to FIG. 10, the non-volatile memory device 200 may include a peripheral circuit stack PS and a cell array stack CS on the peripheral circuit stack PS. The description of the peripheral circuit stack PS of the non-volatile memory device 100 given with reference to FIGS. 3 to 7 may be referred to for the peripheral circuit stack PS of the non-volatile memory device 200. The description of the first cell array stack CS1 of the non-volatile memory device 100 given with reference to FIGS. 3 to 7 may be referred to for the cell array stack CS of the non-volatile memory device 200.

In embodiments, the cell array stack CS may include a bit line 210, a plurality of gate lines 230, channel structures 240, and a common source line 250.

The gate lines 230 may be arranged above the bit line 210 apart from each other in a vertical direction (Z direction). The gate lines 230 may include a string selection line 231, one or more dummy word lines 232, word lines 233, and a ground selection line 234. The gate lines 230 may be alternately stacked together with a plurality of mold insulating layers ML. Cut structures 238 may penetrate the string selection line 231.

The channel structures 240 may be provided in channel holes 240H while penetrating the gate lines 230 and may be connected to the bit line 210 at ends thereof and to the common source line 250 at the other ends thereof. For example, the ends of the channel structures 240 may be connected to the bit line 210 through bit line pads 249 and bit line contacts 215. The other ends of the channel structures 240 may be connected to the common source line 250 through source line pads 248 and source line contacts 252.

The descriptions of the first channel holes 140H and the first channel structures 140 given with reference to FIGS. 3 to 7 may be referred to for the channel structures 240 and the channel holes 240H.

Referring to FIG. 11, the non-volatile memory device 300 may include a peripheral circuit stack PS, a first cell array stack CS1 on the peripheral circuit stack PS, and a second cell array stack CS2 on the first cell array stack CS1. The description of the peripheral circuit stack PS of the non-volatile memory device 100 given with reference to FIGS. 3 to 7 may be referred to for the peripheral circuit stack PS of the non-volatile memory device 300. The description of the first cell array stack CS1 of the non-volatile memory device 100 given with reference to FIGS. 3 to 7 may be referred to for the first cell array stack CS1 and the second cell array stack CS2.

In embodiments, the first cell array stack CS1 may include a first bit line 310, a plurality of first gate lines 330, first channel structures 340, and a first common source line 350.

The first gate lines 330 may be arranged above the first bit line 310 apart from each other in a vertical direction (Z direction). The first gate lines 330 may include a first string selection line 331, one or more first dummy word lines 332, first word lines 333, and a first ground selection line 334. The first gate lines 330 may be alternately stacked together with a plurality of mold insulating layers ML. First cut structures 338 may penetrate the first string selection line 331.

The first channel structures 340 may be provided in first channel holes 340H while penetrating the first gate lines 330 and may be connected to the first bit line 310 at ends thereof and to the first common source line 350 at the other ends thereof. For example, the ends of the first channel structures 340 may be connected to the first bit line 310 through first bit line pads 349 and first bit line contacts 315. The other ends of the first channel structures 340 may be connected to the first common source line 350 through first source line pads 348 and first source line contacts 352.

The descriptions of the first channel holes 140H and the first channel structures 140 given with reference to FIGS. 3 to 7 may be referred to for the first channel structures 340 and the first channel holes 340H.

The second cell array stack CS2 may be disposed on the first cell array stack CS1. The second cell array stack CS2 may include a second bit line 360, a plurality of second gate lines 380, second channel structures 390, and a second common source line 355. The structure of the second cell array stack CS2 of the non-volatile memory device 300 may be substantially similar and/or the same as the structure of the first cell array stack CS1 of the non-volatile memory device 300.

The second gate lines 380 may be arranged above the second bit line 360 apart from each other in the vertical direction (Z direction). For example, the second gate lines 380 and a plurality of mold insulating layers ML may be alternately arranged above the second bit line 360.

In embodiments, the second gate lines 380 may include a second string selection line 381, second dummy word lines 382, second word lines 383, and a second ground selection line 384 that are sequentially arranged above the second bit line 360. Second cut structures 388 may penetrate the second string selection line 381.

The second channel structures 390 may be disposed in second channel holes 390H that extend through the second gate lines 380 in the vertical direction (Z direction).

The second bit line 360 may be disposed on the second channel structures 390 and connected to the second channel structures 390 through second bit line contacts 365. For example, the second bit line 360 may be connected to channel layers of the second channel structures 390 through the second bit line contact 365 and second bit line pads 399. The second bit line pads 399 may be buried in a second substrate 370.

The second common source line 355 may be connected to the second channel structures 390 through second source line contacts 357. For example, the second common source line 355 may be connected to the channel layers of the second channel structures 390 through the second source line contacts 357 and second source line pads 398.

In embodiments, the second bit line 360 of the second cell array stack CS2 may be disposed between the second channel structures 390 and the first cell array stack CS1. In embodiments, the second common source line 355 of the second cell array stack CS2 may be apart from the second bit line 360 with the second channel structures 390 therebetween.

The descriptions of the first channel holes 140H and the first channel structures 140 given with reference to FIGS. 3 to 7 may be referred to for the second channel structures 390 and the second channel holes 390H.

FIGS. 12 to 26 are cross-sectional diagrams illustrating a method of manufacturing a non-volatile memory device, according to embodiments. For example, FIGS. 12 to 26 are cross-sectional diagrams illustrating a method of manufacturing some elements of the non-volatile memory device 100 described with reference to FIGS. 3 to 7. As another example, FIGS. 12 to 26 are cross-sectional diagrams illustrating a method of manufacturing the first cell array stack CS1 shown in FIG. 5.

Referring to FIG. 12, a plurality of mold insulating layers ML and a plurality of first sacrificial layers S131 may be alternately formed on a substrate 102. In embodiments, the substrate 102 may be a single-crystal silicon substrate. In embodiments, the mold insulating layers ML may include an insulating material such as, but not limited to, silicon oxide (SiO), silicon oxynitride (SiON), or the like, and the first sacrificial layers S131 may include a material such as, but not limited to, silicon nitride (SiN), silicon oxynitride (SiON), or polysilicon doped with a dopant. For example, the vertical thickness of a mold insulating layer ML disposed on an uppermost first sacrificial layer S131 among the mold insulating layers ML may be greater than the vertical thicknesses of the other mold insulating layers ML.

Referring to FIG. 13, the mold insulating layers ML, the first sacrificial layers S131, and a portion of the substrate 102 may be etched to form first holes H1. The substrate 102, the mold insulating layers ML, and the first sacrificial layers S131 may be exposed through the first holes H1.

The first holes H1 may penetrate the mold insulating layers ML and the first sacrificial layers S131. The first holes H1 may penetrate the mold insulating layers ML and the first sacrificial layers S131 in a vertical downward direction (−Z direction). That is, the horizontal widths of upper portions (e.g., portions having a relatively high vertical level) of the first holes H1 may be greater than the horizontal widths of lower portions (e.g., portions having a relatively low vertical level) of the first holes H1.

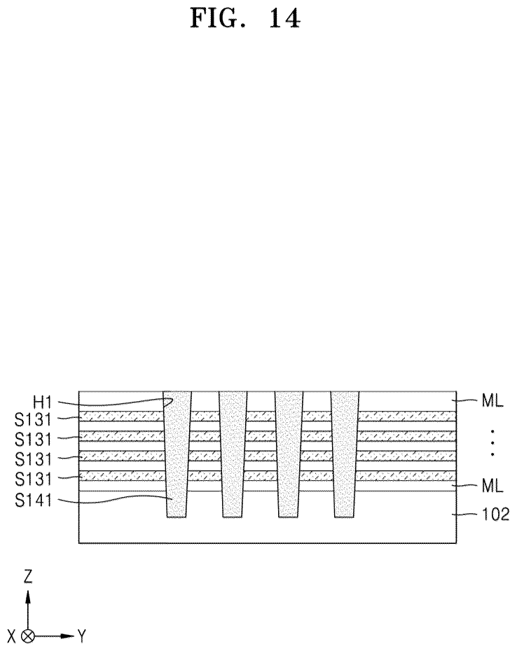

Referring to FIG. 14, first sacrificial structures S141 may be formed in the first holes H1. The first sacrificial structures S141 may penetrate the mold insulating layers ML and the first sacrificial layers S131 in a vertical direction (Z direction). In embodiments, the first sacrificial structures S141 may include a metallic material such as, but not limited to, carbon (C) or tungsten (W).

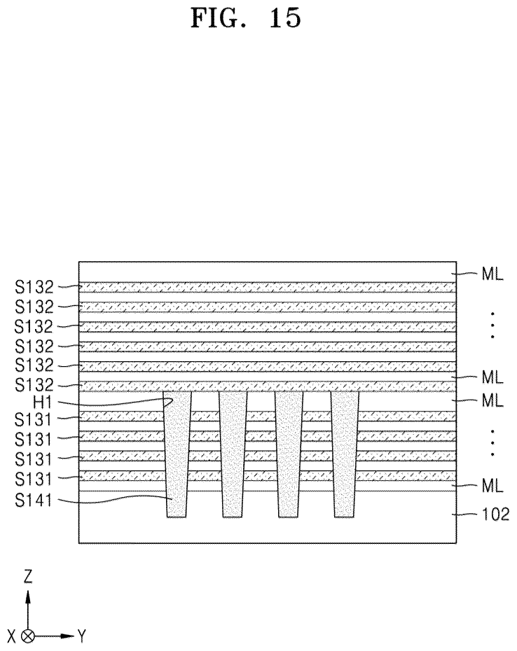

Referring to FIG. 15, a plurality of mold insulating layers ML and a plurality of second sacrificial layers S132 may be formed on the first sacrificial structures S141, the mold insulating layers ML surrounding the first sacrificial structures S141, and the first sacrificial layers S131 surrounding the first sacrificial structures S141. The second sacrificial layers S132 may include the same material as the first sacrificial layers S131.

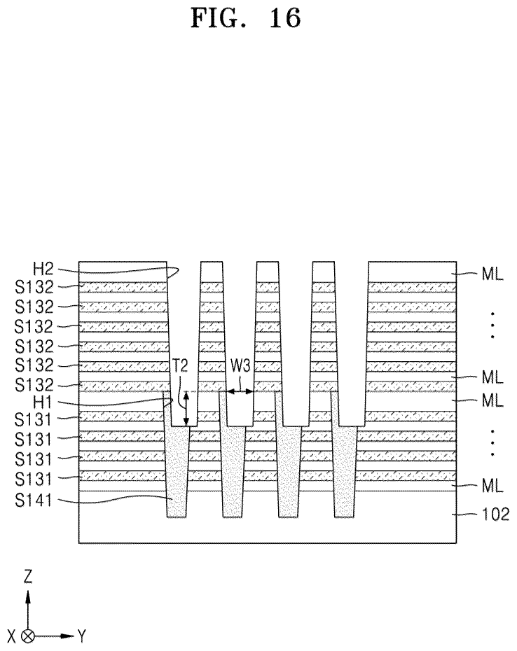

Referring to FIG. 16, the mold insulating layers ML and the second sacrificial layers S132 may be etched to form second holes H2. When the second holes H2 are formed, portions of the mold insulating layers ML, the first sacrificial layers 131, and the first sacrificial structures S141 that are disposed below the second sacrificial layers S132 may also be etched. For example, the second holes H2 may overlap the first holes H1 in the vertical direction (Z direction).

In embodiments, at least portions of the second holes H2 may overlap the first holes H1 in a horizontal direction (e.g., a second horizontal direction (Y direction)). For example, the first sacrificial structures S141 may include at least portions that overlap the second holes H2 in the second horizontal direction (Y direction).

In embodiments, the centers of the second holes H2 may be offset from the centers of the first holes H1. For example, at least portions of outer walls of the second holes H2 may not overlap the first holes H1.

In embodiments, the second holes H2 may sufficiently overlap the first holes H1. For example, an overlap depth (e.g., T2) between the second holes H2 and the first holes H1 may be greater than or equal to a horizontal width (e.g., a third width W3) of the second holes H2 at boundaries between portions of the second holes H2 overlapping the first holes H1 in the second horizontal direction (Y direction) and portions of the second holes H2 not overlapping the first holes H1 in the second horizontal direction (Y direction). Consequently, as described with reference to FIG. 7, in each of the first channels holes 140H, the vertical thickness T1 of the third portion 140H_3 may be greater than or equal to the horizontal width W2 of the second portion 140H_2 at the boundary between the second portion 140H_2 and the third portion 140H_3.

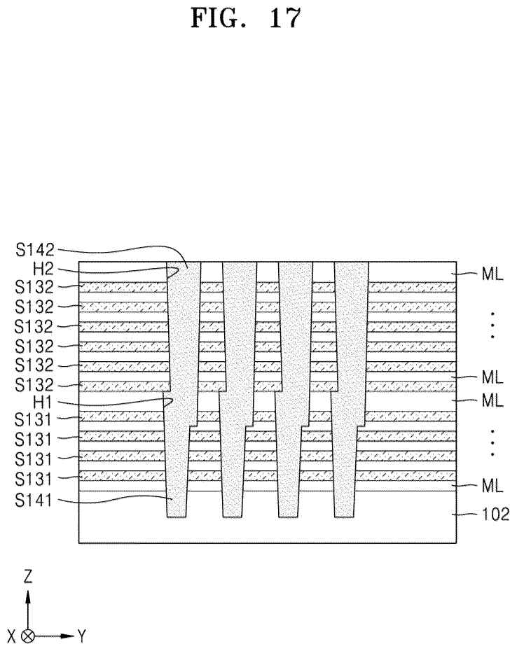

Referring to FIG. 17, second sacrificial structures S142 may be formed in the second holes H2. The second sacrificial structures S142 may penetrate the mold insulating layers ML and the second sacrificial layers S132 in the vertical direction (Z direction). The second sacrificial structures S142 may include the same material as the first sacrificial structures S141. The second sacrificial structures S142 may penetrate portions of the mold insulating layers ML and the first sacrificial layers S131 that may be disposed below the second sacrificial layers S132.

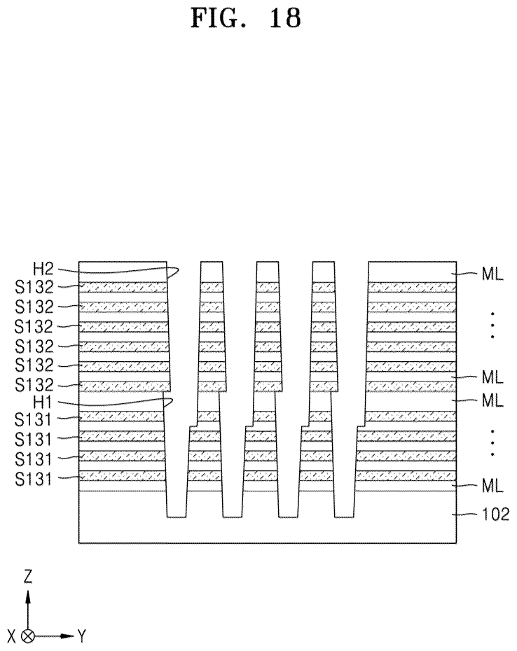

Referring to FIG. 18, the first sacrificial structures S141 and the second sacrificial structures S142 may be removed. As a result, inner walls of the first holes H1 and the second holes H2 and portions of the substrate 102 may be exposed.

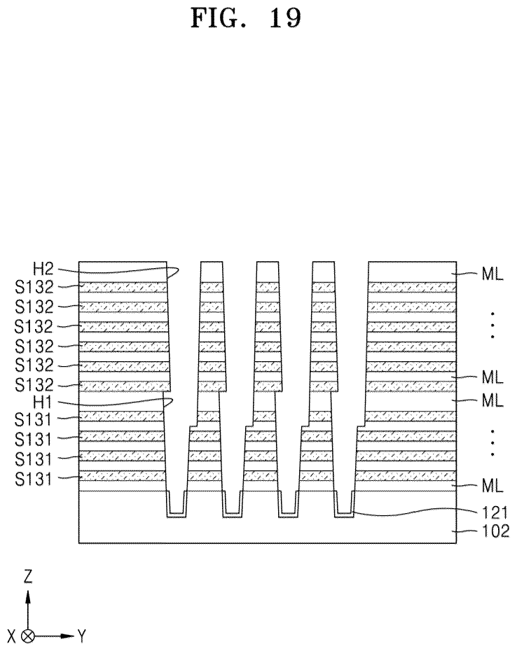

Referring to FIG. 19, insulating liners 121 may be formed in lower portions of the first holes H1. For example, an oxidation process may be performed on the substrate 102 exposed through the lower portions of the first holes H1 to form the insulating liners 121.

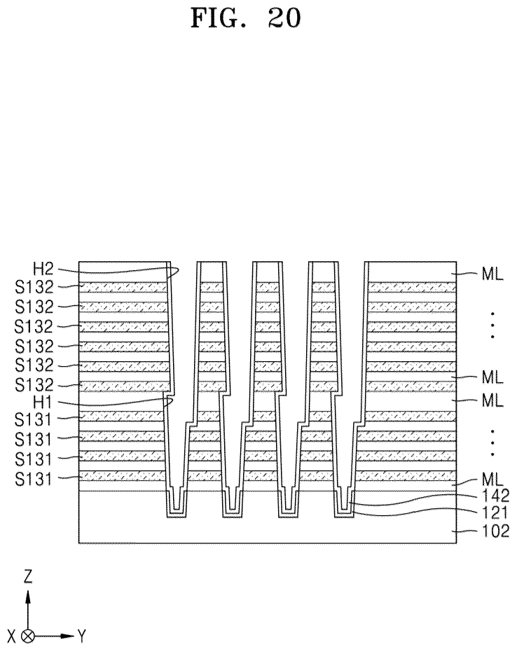

Referring to FIG. 20, gate insulating layers 142 may be formed on the inner walls of the first holes H1 and the second holes H2. In the lower portions of the first holes H1, the gate insulating layers 142 may be formed on the insulating liners 121. In embodiments, the gate insulating layers 142 may be conformally formed on the inner walls of the first holes H1 and the second holes H2. In embodiments, the gate insulating layers 142 may each be formed as one body on the inner walls of the first holes H1 and the second holes H2. For example, at boundaries between the first holes H1 and the second holes H2, each of the gate insulating layers 142 may be formed as one body without being divided.

As described above, the second holes H2 may sufficiently overlap the first holes H1, and thus, the gate insulating layers 142 may be conformally formed on the inner walls of the first holes H1 and the second holes H2 without blocking middle portions at the boundaries between the first holes H1 and the second holes H2.

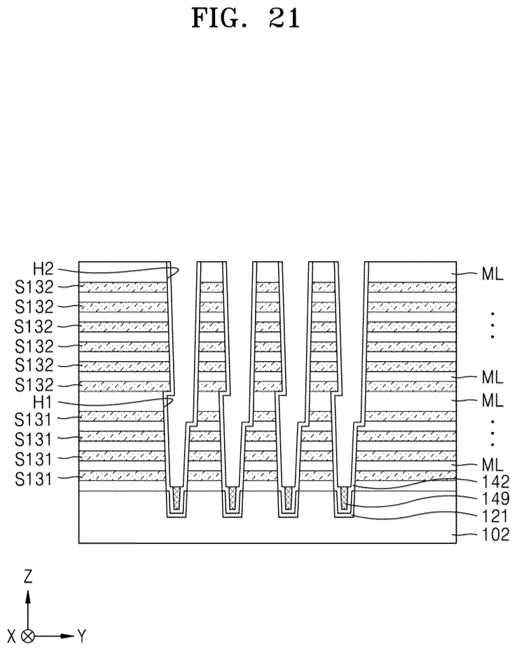

Referring to FIG. 21, first bit line pads 149 may be formed in the lower portions of the first holes H1. The first bit line pads 149 may be surrounded by the insulating liners 121.

For example, the first bit line pads 149 may be formed by forming pad liners on the gate insulating layers 142 within the first holes H1 and the second holes H2. The pad liners may fill the lower portions of the first holes H1 having a relatively small horizontal width, and the remaining portions of the pad liners may be removed to form the first bit line pads 149.

In embodiments, the first bit line pads 149 may include, but not be limited to, polysilicon doped with an n-type dopant.

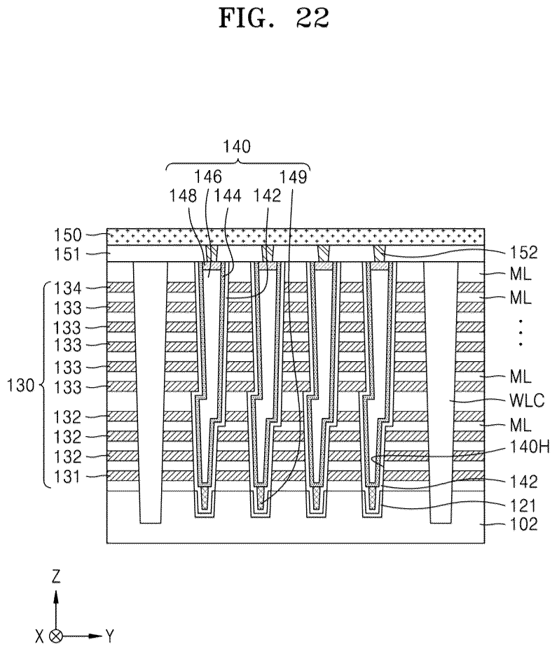

Referring to FIG. 22, first channel structures 140 may be formed. For example, channel layers 144 may be formed on the gate insulating layers 142 and the first bit line pads 149, and then, buried insulating layers 146 may be formed on the channel layers 144 to fill the remaining spaces of the first holes H1 and the second holes H2. Thereafter, first source line pads 148 may be formed on the channel layers 144 and the buried insulating layers 146. The first holes H1 and the second holes H2 may together form the first channel holes 140H.

Thereafter, portions of the mold insulating layers ML, the first sacrificial layers S131, and the second sacrificial layers S132 may be removed, and word line cut structures WLC may be formed through the mold insulating layers ML, the first sacrificial layers S131, and the second sacrificial layers S132.

Thereafter, the first sacrificial layers S131 and the second sacrificial layers S132 may be removed, and a conductive material may be applied to form a plurality of gate lines 130.

Thereafter, a second insulating layer 151 may be applied to the first channel structures 140, and first source line contacts 152 may be formed through the second insulating layer 151 such that the first source line contacts 152 may be connected to the first source line pads 148. A first common source line 150 may be formed on the first source line contacts 152.

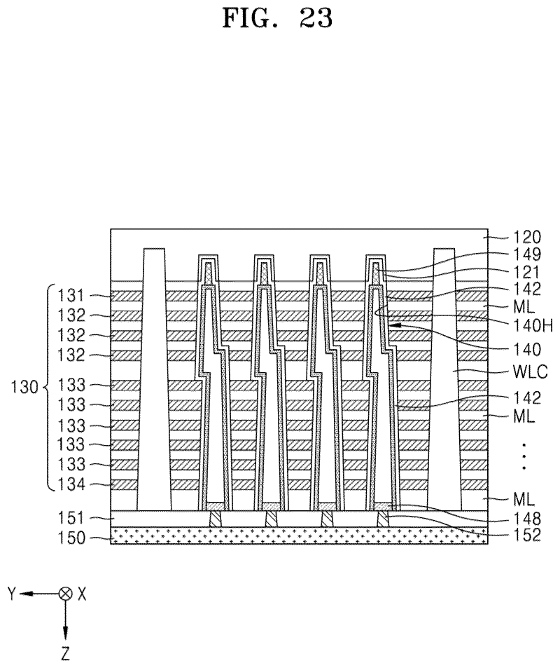

Referring to FIG. 23, a resultant structure shown in FIG. 22 may be flipped in the vertical direction (Z direction). Subsequently, the substrate 102 may be removed, and a first substrate 120 including an oxide may be formed.

For example, a carrier wafer may be bonded to the substrate 102, and the resultant structure shown in FIG. 22 may be flipped in the vertical direction (Z direction).

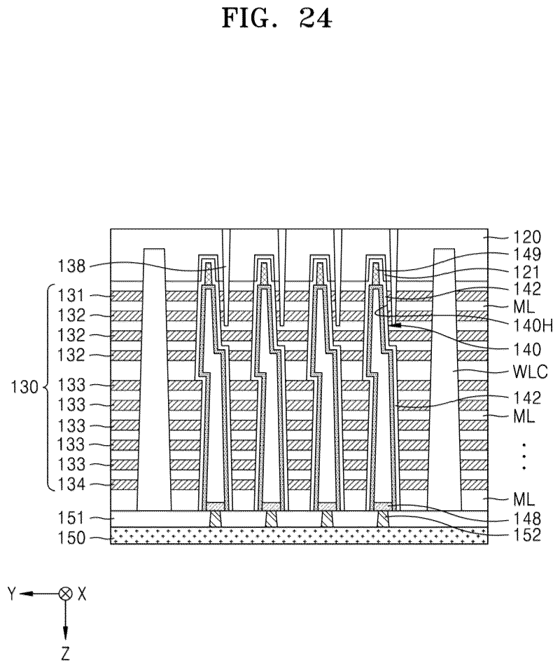

Referring to FIG. 24, in the resultant structure shown in FIG. 23, first cut structures 138 penetrating the first substrate 120 and some of the mold insulating layers ML and the first gate lines 130 may be formed. For example, the first cut structures 138 may penetrate some of the mold insulating layers ML and the first gate lines 130 that are adjacent to the first substrate 120. As another example, some of the first gate lines 130 through which the first cut structures 138 penetrate may be a first string selection line 131 (as shown in FIGS. 5 and 6) and a first dummy word line 132 (as shown in FIGS. 5 and 6).

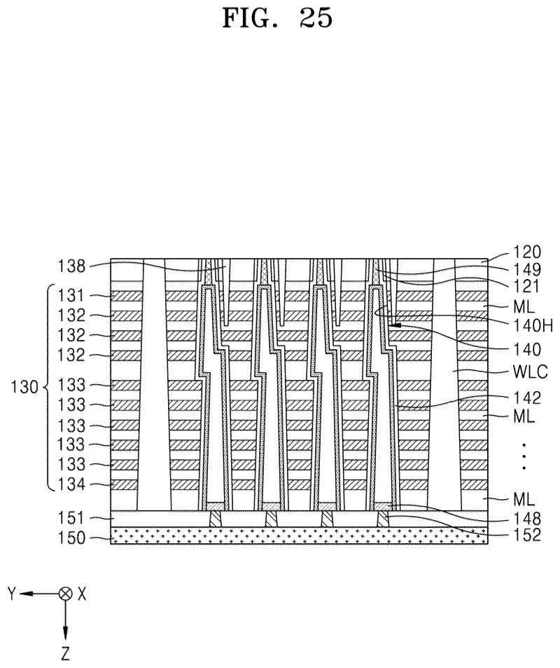

Referring to FIG. 25, a portion of the first substrate 120 may be removed to expose the first bit line pads 149. For example, the first substrate 120, the word line cut structures WLC, and the insulating liners 121 may be removed until the first bit line pads 149 are exposed. As another example, the first substrate 120, the word line cut structures WLC, and the insulating liners 121 may be removed until the first bit line pad 149 is exposed.

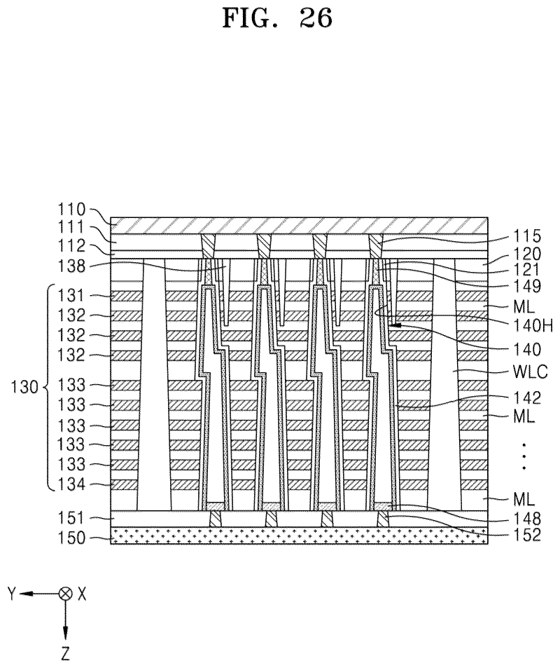

Referring to FIG. 26, an etch stop layer 112 and a first insulating layer 111 may be formed on the first substrate 120, and subsequently, first bit line contacts 115 may be formed such that the first bit line contacts 115 may be connected to the first bit line pads 149 through the first insulating layer 111 and the etch stop layer 112. Thereafter, a first bit line 110 may be formed on the first bit line contacts 115 and the first insulating layer 111.

Hereinafter, subsequent processes for forming the non-volatile memory device 100 are described by referring to FIG. 5 together.

In a resultant structure shown in FIG. 26, a first bonding layer BI1 and first bonding pads BP1 may be formed on the first bit line 110. Thereafter, a peripheral circuit stack PS on which a first bonding layer BI1 and first bonding pads BP1 are formed may be prepared. The resultant structure shown in FIG. 26 may be bonded to the peripheral circuit stack PS using the first bonding layers BI1 and the first bonding pads BP1.

Thereafter, a second bonding layer BI2 and second bonding pads BP2 may be formed on the first common source line 150 to form a first cell array stack CS1. A second cell array stack CS2 on which a second bonding layer BI2 and second bonding pads BP2 are formed may be prepared, and subsequently, the second cell array stack CS2 may be bonded to the first cell array stack CS1 using the second bonding layers BI2 and the second bonding pads BP2. The second cell array stack CS2 may be manufactured and provided by a method similar to the method described with reference to FIGS. 12 to 26.

The non-volatile memory device 100 may be manufactured using the non-volatile memory device manufacturing method described above with reference to FIGS. 12 to 26 and FIG. 5.

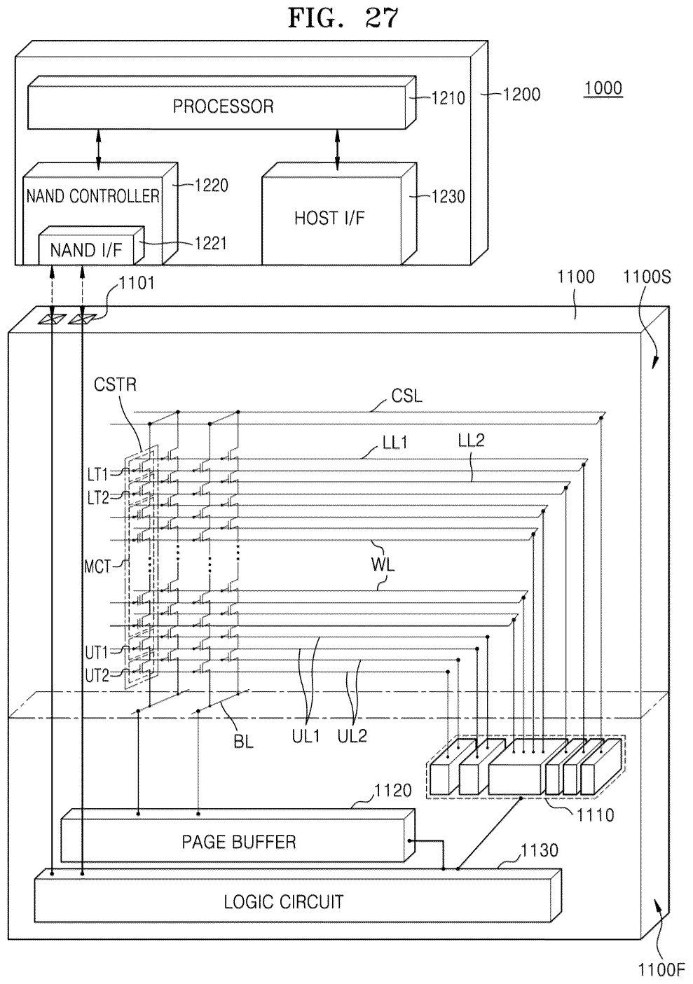

FIG. 27 is a diagram schematically illustrating a data storage system 1000 including at least one non-volatile memory device 1100, according to embodiments.

Referring to FIG. 27, the data storage system 1000 may include the at least one non-volatile memory device 1100 and a memory controller 1200 electrically connected to the at least one non-volatile memory device 1100. The data storage system 1000 may be, for example, a solid state drive (SSD) device, a universal serial bus (USB) device, a computing system, a medical device, and/or a communication device including the at least one non-volatile memory device 1100.

For example, the at least one non-volatile memory device 1100 may be a NAND flash non-volatile memory device including one of the non-volatile memory devices 100, 100A, 100B, 200, and 300 described with reference to FIGS. 3 to 11. The at least one non-volatile memory device 1100 may include a first structure 1100F and a second structure 1100S provided on the first structure 1100F. The first structure 1100F may be and/or may include a peripheral circuit structure including a row decoder 1110, a page buffer 1120, and a logic circuit 1130.

The second structure 1100S may be a memory cell structure that includes bit lines BL, a common source line CSL, a plurality of word lines WL, first and second string selection lines UL1 and UL2, first and second ground selection lines LL1 and LL2, and a plurality of memory cell strings CSTR between the bit lines BL and the common source line CSL.

In the second structure 1100S, each of the memory cell strings CSTR may include ground selection transistors (e.g., a first ground selection transistor LT1 and a second ground selection transistor LT2) adjacent to the common source line CSL, string selection transistors (e.g., a first string selection transistor UT1 and a second string selection transistor UT1) adjacent to the bit lines BL, and a plurality of memory cell transistors MCT between the first and second ground selection transistors LT1 and LT2 and the first and second string selection transistors UT1 and UT2. The number of ground selection transistors LT1 and LT2 and the number of string selection transistors UT1 and UT2 may vary depending on embodiments and/or design constraints.

In embodiments, the first and second ground selection lines LL1 and LL2 may be connected to gate electrodes of the first and second ground selection transistors LT1 and LT2, respectively. The word lines WL may be connected to gate electrodes of the memory cell transistors MCT. The first and second string selection lines UL1 and UL2 may be connected to gate electrodes of the first and second string selection transistors UT1 and UT2, respectively.

The common source line CSL, the first and second ground selection lines LL1 and LL2, the word lines WL, and the first and second string selection lines UL1 and UL2 may be connected to the row decoder 1110. The bit lines BL may be electrically connected to the page buffer 1120.

The at least one non-volatile memory device 1100 may communicate with the memory controller 1200 through I/O pads 1101 that are electrically connected to the logic circuit 1130. The I/O pads 1101 may be electrically connected to the logic circuit 1130.

The memory controller 1200 may include a processor 1210, a NAND controller 1220, and a host interface 1230. In some embodiments, the data storage system 1000 may include a plurality of non-volatile memory devices 1100, and the memory controller 1200 may control the non-volatile memory devices 1100.

The processor 1210 may control the overall operation of the data storage system 1000 including the memory controller 1200. The processor 1210 may operate according to firmware and may control the NAND controller 1220 to access the at least one non-volatile memory device 1100. The NAND controller 1220 may include a NAND interface 1221 that may control communication with the at least one non-volatile memory device 1100. Data, such as, but not limited to, control commands for controlling the at least one non-volatile memory device 1100, data to be written to the memory cell transistors MCT of the at least one non-volatile memory device 1100, and data to be read from the memory cell transistors MCT, may be transmitted through the NAND interface 1221. The host interface 1230 may provide a communication function between the data storage system 1000 and an external host. For example, when the processor 1210 receives a control command from an external host through the host interface 1230, the processor 1210 may control the at least one non-volatile memory device 1100 in response to the control command.

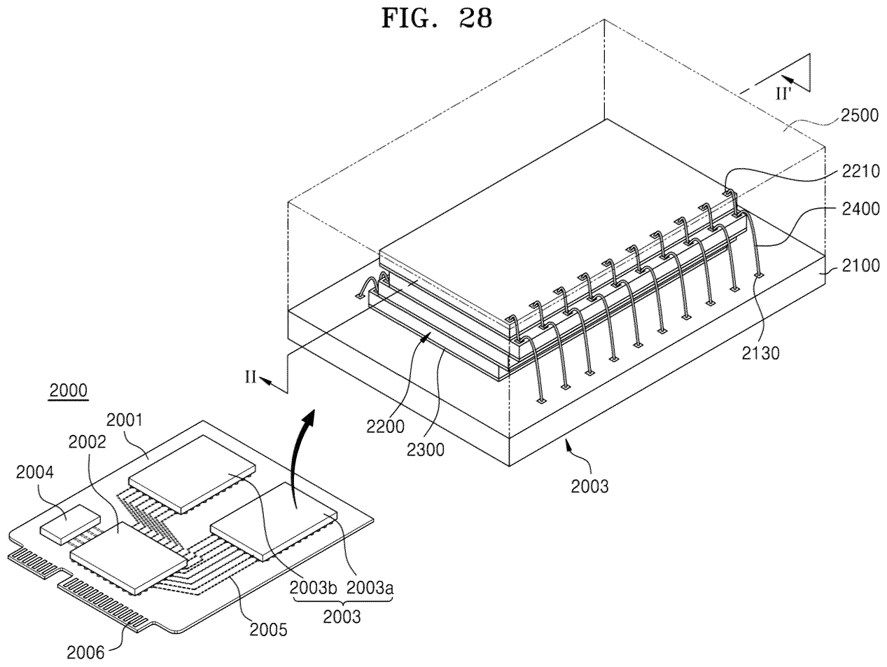

FIG. 28 is a perspective diagram schematically illustrating a data storage system 2000 including non-volatile memory devices, according to embodiments.

Referring to FIG. 28, according to embodiments, the data storage system 2000 may include a main board 2001, a memory controller 2002 mounted on the main board 2001, one or more semiconductor packages 2003, and a dynamic random-access memory (DRAM) 2004. The semiconductor packages 2003 and the DRAM 2004 may be connected to the memory controller 2002 through a plurality of wiring patterns 2005 formed on the main board 2001.

The main board 2001 may include a connector 2006 including a plurality of pins that may be coupled to an external host. The number and arrangement of the pins of the connector 2006 may vary depending on a communication interface between the data storage system 2000 and the external host. In embodiments, the data storage system 2000 may communicate with the external host through one of interfaces such as universal serial bus (USB), peripheral component interconnect express (PCI-Express), serial advanced technology attachment (SATA), or M-Phy for universal flash storage (UFS). In embodiments, the data storage system 2000 may operate with power supplied from the external host through the connector 2006. The data storage system 2000 may further include a power management integrated circuit (PMIC) configured to distribute power supplied from an external host to the memory controller 2002 and the semiconductor packages 2003.

The memory controller 2002 may write data to the semiconductor packages 2003, read data from the semiconductor packages 2003, and improve the operating speed of the data storage system 2000.

The DRAM 2004 may be a buffer memory configured to reduce a speed difference between the semiconductor packages 2003 (e.g., data storage space) and the external host. The DRAM 2004 included in the data storage system 2000 may operate as a type of cache memory and may provide space for temporarily storing data when a control operation is performed on the semiconductor packages 2003. When the data storage system 2000 includes the DRAM 2004, the memory controller 2002 may further include a DRAM controller configured to control the DRAM 2004 in addition to a NAND controller configured to control the semiconductor packages 2003.

The semiconductor packages 2003 may include a first semiconductor package 2003a and a second semiconductor package 2003b that may be arranged apart from each other. Each of the first and second semiconductor packages 2003a and 2003b may include a plurality of semiconductor chips 2200. Each of the first and second semiconductor packages 2003a and 2003b may include a package substrate 2100, the semiconductor chips 2200 provided on the package substrate 2100, an adhesive layer 2300 provided on a lower surface of each of the semiconductor chips 2200, connection structures 2400 electrically connecting the semiconductor chips 2200 and the package substrate 2100 to each other, and a molding layer 2500 provided on the package substrate 2100 to cover the semiconductor chips 2200 and the connection structures 2400.

The package substrate 2100 may be a printed circuit board including a plurality of upper package pads 2130. Each of the semiconductor chips 2200 may include I/O pads 2210. The I/O pads 2210 may correspond to the I/O pads 1101 shown in FIG. 27. Each of the semiconductor chips 2200 may include at least one of the non-volatile memory devices 100, 100A, 100B, 200, and 300 described with reference to FIGS. 3 to 11.

In embodiments, the connection structures 2400 may be and/or may include bonding wires that electrically connect the I/O pads 2210 and the upper package pads 2130 to each other. Therefore, in each of the first and second semiconductor packages 2003a and 2003b, the semiconductor chips 2200 may be electrically connected to each other by a wire bonding method and may be electrically connected to the upper package pads 2130 of the package substrate 2100. In embodiments, the semiconductor chips 2200 of each of the first and second semiconductor packages 2003a and 2003b may be electrically connected to each other through connection structures including through-silicon vias (TSVs) instead of a wire bonding method using the connection structures 2400.

In embodiments, the memory controller 2002 and the semiconductor chips 2200 may be included in one package. In embodiments, the memory controller 2002 and the semiconductor chips 2200 may be mounted on an additional interposer board different from the main board 2001 and may be connected to each other through wiring formed on the additional interposer board.

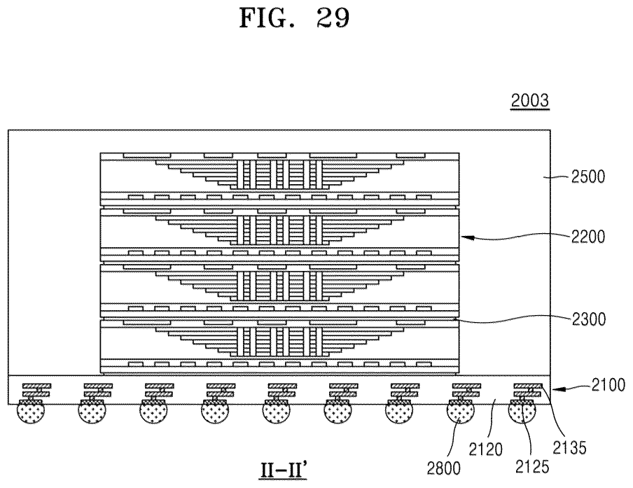

FIG. 29 is a cross-sectional diagram schematically illustrating a semiconductor package 2003, according to embodiments. For example, FIG. 29 may be a cross-sectional diagram taken along line II-II′ of FIG. 28.

Referring to FIG. 29, a package substrate 2100 of the semiconductor package 2003 may be a printed circuit board. The package substrate 2100 may include a package substrate body 2120, a plurality of upper package pads 2130 (as shown in FIG. 28) arranged on an upper surface of the package substrate body 2120, a plurality of lower pads 2125 arranged on a lower surface of the package substrate body 2120 or exposed through the lower surface of the package substrate body 2120, and a plurality of internal wiring lines 2135 provided in the package substrate body 2120 to electrically connect the upper package pads 2130 (as shown in FIG. 28) and the lower pads 2125 to each other. The upper package pads 2130 may be electrically connected to the connection structures 2400. The lower pads 2125 may be connected through a plurality of conductive bumps 2800 to the wiring patterns 2005 (as shown in FIG. 28) formed on the main board 2001 of the data storage system 2000. Each of semiconductor chips 2200 may include at least one of the non-volatile memory devices 100, 100A, 100B, 200, and 300 described with reference to FIGS. 3 to 11.

While the present disclosure has been particularly shown and described with reference to embodiments thereof, it is to be understood that various changes in form and details may be made therein without departing from the spirit and scope of the following claims.

What is claimed is:

1. A non-volatile memory device, comprising:
a plurality of gate lines comprising a string selection line, a word line above the string selection line, and a dummy word line between the string selection line and the word line, the plurality of gate lines being disposed apart from each other in a vertical direction;
a cut structure at least partially penetrating the string selection line in the vertical direction;
a channel structure disposed in a channel hole that at least partially penetrates the plurality of gate lines in the vertical direction;
a bit line coupled with a first end of the channel structure; and
a common source line coupled with a second end of the channel structure,
wherein the channel hole comprises a first portion at least partially penetrating the string selection line, a second portion at least partially penetrating the word line, and a third portion disposed between the first portion and the second portion and coupled in one piece with the first portion and the second portion,
wherein the first portion is offset from the second portion in a horizontal direction crossing the vertical direction,
wherein the channel structure comprises a gate insulating layer conformally disposed on an inner wall of the channel hole, and a channel layer conformally disposed on the gate insulating layer,
wherein the gate insulating layer is disposed as one body on inner walls of the first portion, the second portion, and the third portion.

2. The non-volatile memory device of claim 1, wherein the channel hole further comprises a fourth portion between the first portion and the bit line,
wherein the channel structure further comprises a bit line pad in the fourth portion, and
wherein, at a boundary between the first portion and the fourth portion, a first horizontal width of the first portion is greater than a second horizontal width of the fourth portion.

3. The non-volatile memory device of claim 2, wherein the channel layer is electrically coupled with the bit line through the bit line pad.

4. The non-volatile memory device of claim 1, wherein each of the first portion, the second portion, and the third portion does not comprise a step on an outer wall thereof.

5. The non-volatile memory device of claim 1, wherein the cut structure at least partially overlaps at least a portion of the second portion of the channel hole in the vertical direction.

6. The non-volatile memory device of claim 1, wherein the third portion at least partially overlaps at least a portion of the dummy word line in the horizontal direction.

7. The non-volatile memory device of claim 1, wherein a horizontal width of the second portion at a boundary between the second portion and the third portion is less than or equal to a vertical thickness of the third portion.

8. The non-volatile memory device of claim 1, wherein the cut structure does not overlap the first portion of the channel hole in the vertical direction.

9. The non-volatile memory device of claim 1, further comprising:
a common source line contact between the common source line and the second end of the channel structure.

10. The non-volatile memory device of claim 1, wherein a first width in the horizontal direction of a first region of the first portion gradually increases in a first direction from the bit line toward the common source line,
wherein a second width in the horizontal direction of a second region of the second portion gradually increases in a second direction away from the first portion,
wherein, at a first boundary between the first portion and the third portion, a first horizontal width of the first portion is less than a third horizontal width of the third portion, and
wherein, at a second boundary between the second portion and the third portion, a second horizontal width of the second portion is less than the third horizontal width of the third portion.

11. The non-volatile memory device of claim 1, wherein a first maximum horizontal width of the first portion of the channel hole is less than a second maximum horizontal width of the channel hole.

12. A non-volatile memory device, comprising:
a peripheral circuit stack comprising a peripheral circuit board and a peripheral circuit on the peripheral circuit board; and
a first cell array stack on the peripheral circuit stack,
wherein the first cell array stack comprises:
a plurality of first gate lines comprising a first string selection line, a first word line above the first string selection line, and a first dummy word line between the first string selection line and the first word line, the plurality of first gate lines being disposed apart from each other in a vertical direction;
a first cut structure at least partially penetrating the first string selection line in the vertical direction;
a first channel structure comprising a first channel layer disposed in a first channel hole that at least partially penetrates the plurality of first gate lines in the vertical direction;
a first bit line coupled with the first channel layer through a first bit line pad at a first end of the first channel structure; and
a first common source line coupled with the first channel layer at a second end of the first channel structure,
wherein the first channel hole comprises a first portion at least partially penetrating the first string selection line and a second portion at least partially penetrating the first word line,
wherein a first width in a horizontal direction of a first region of the first portion gradually increases in a first direction from the first bit line toward the first common source line, the horizontal direction crossing the vertical direction,
wherein a second width in the horizontal direction of a second region of the second portion gradually increases in a second direction away from the first portion, and
wherein the first portion is offset from the second portion in the horizontal direction.

13. The non-volatile memory device of claim 12, wherein the first channel hole further comprises a third portion between the first portion and the second portion,
wherein the third portion is coupled in one piece with the first portion and the second portion,
wherein, at a first boundary between the first portion and the third portion, a first horizontal width of the first portion is less than a third horizontal width of the third portion,
wherein, at a second boundary between the second portion and the third portion, a second horizontal width of the second portion is less than the third horizontal width of the third portion, and
wherein each of the first portion, the second portion, and the third portion does not comprise a step on an outer wall thereof.

14. The non-volatile memory device of claim 13, wherein the first channel structure further comprises a gate insulating layer conformally disposed between an inner wall of the first channel hole and the first channel layer, and
wherein the gate insulating layer is disposed as one body on inner walls of the first portion, the second portion, and the third portion.

15. The non-volatile memory device of claim 13, wherein the third portion at least partially overlaps at least a portion of the first dummy word line in the horizontal direction.

16. The non-volatile memory device of claim 13, wherein the first channel layer is disposed as one body on inner walls of the first portion, the second portion, and the third portion.

17. The non-volatile memory device of claim 12, wherein the first bit line is disposed between the first channel structure and the peripheral circuit stack, and
wherein the first common source line is apart from the first bit line with the first channel structure therebetween.

18. The non-volatile memory device of claim 12, wherein the first common source line is disposed between the first channel structure and the peripheral circuit stack, and
wherein the first common source line is apart from the first bit line with the first channel structure therebetween.

19. The non-volatile memory device of claim 12, further comprising:
a second cell array stack on the first cell array stack,
wherein the second cell array stack comprises:
a plurality of second gate lines disposed apart from each other in the vertical direction;
a second channel structure comprising a second channel layer disposed in a second channel hole that at least partially penetrates the plurality of second gate lines in the vertical direction;
a second bit line coupled with the second channel layer through a second bit line pad at an end of the second channel structure; and
a second common source line coupled with the second channel layer at another end of the second channel structure,
wherein the second channel hole comprises a fifth portion at least partially penetrating a second string selection line of the plurality of second gate lines and a sixth portion at least partially penetrating a second word line of the plurality of second gate lines, and
wherein a first center of the fifth portion is offset in the horizontal direction from a second center of the sixth portion.

20. An electronic system, comprising:
a main board;
a non-volatile memory device on the main board; and
a controller on the main board and electrically coupled with the non-volatile memory device,
wherein the non-volatile memory device comprises:
a peripheral circuit stack comprising a peripheral circuit board and a peripheral circuit on the peripheral circuit board; and
a cell array stack on the peripheral circuit stack,
wherein the cell array stack comprises:
a plurality of gate lines comprising a string selection line, a word line above the string selection line, and a dummy word line between the string selection line and the word line, the plurality of gate lines being disposed apart from each other in a vertical direction;
a cut structure at least partially penetrating the string selection line in the vertical direction;
a channel structure comprising a channel layer disposed in a channel hole that at least partially penetrates the plurality of gate lines in the vertical direction;
a bit line coupled with the channel layer through a bit line pad at an end of the channel structure; and
a common source line coupled with the channel layer at another end of the channel structure,
wherein the channel hole comprises a first portion at least partially penetrating the string selection line, a second portion at least partially penetrating the word line, and a third portion disposed between the first portion and the second portion and coupled in one piece with the first portion and the second portion,
wherein a first width in a horizontal direction of a first region of the first portion gradually increases in a first direction from the bit line toward the common source line, the horizontal direction crossing the vertical direction,
wherein a second width in the horizontal direction of a second region of the second portion gradually increases in a second direction away from the first portion,
wherein, at a first boundary between the first portion and the third portion, a first horizontal width of the first portion is less than a third horizontal width of the third portion,
wherein, at a second boundary between the second portion and the third portion, a second horizontal width of the second portion is less than the third horizontal width of the third portion,
wherein a first center of the first portion is offset in the horizontal direction from a center of the second portion,
wherein the channel structure further comprises a gate insulating layer conformally disposed on an inner wall of the channel hole, and
wherein the gate insulating layer is disposed as one body on inner walls of the first portion, the second portion, and the third portion.
